(19) United States
(12) Patent Application Publication
(10) Pub. No.: US 2025/0055472 A1
(43) Pub. Date: Feb. 13, 2025

(54) SEMICONDUCTOR DEVICE

(71) Applicant: Renesas Electronics Corporation, Tokyo (JP)

(72) Inventors: Tomohiko EBATA, Tokyo (JP); Tetsuo MATSUI, Tokyo (JP)

(73) Assignee: Renesas Electronics Corporation, Tokyo (JP)

(21) Appl. No.: 18/799,138

(22) Filed: Aug. 9, 2024

(30) Foreign Application Priority Data
Aug. 9, 2023 (JP) 2023-129839

(51) Int. Cl. H03M 1/46; H03M 1/12; H03M 1/14

(52) U.S. Cl. CPC H03M 1/468; H03M 1/124; H03M 1/145

(57) ABSTRACT

A semiconductor device is provided. The semiconductor device is capable of operating accurately by suppressing errors caused by dielectric relaxation phenomena. The semiconductor device includes a first capacitive element, a signal cancellation circuit, a sampling circuit, a negative feedback circuit, an AD converter, and an addition-and-subtraction circuit.

### CROSS-REFERENCE TO RELATED APPLICATION

The subject application claims priority under 35 U.S.C. § 119 to Japanese Patent Application No. 2023-129839 filed on Aug. 9, 2023. The entire disclosure of Japanese Patent Application No. 2023-129839 is incorporated herein by reference.

### BACKGROUND

This disclosure relates to a semiconductor device, for example, a semiconductor device capable of operating accurately by suppressing errors caused by dielectric relaxation phenomena.

There are disclosed techniques listed below.
[Patent Document 1] Japanese Unexamined Patent Application Publication No. 2020-107985

In Patent Document 1, a charge redistribution type sequential comparison type AD conversion circuit that suppresses errors in AD conversion caused by dielectric relaxation phenomena is disclosed.

### SUMMARY

Not limited to the charge redistribution type sequential comparison type AD conversion circuit disclosed in Patent Document 1, it is required to suppress errors caused by dielectric relaxation phenomena and operate accurately in AD conversion circuits where the capacitive element for sampling and the capacitive element for DA conversion are separated, and in top plate sampling type AD conversion circuits.

Other objects and novel features will become apparent from the description of this specification and the accompanying drawings.

A semiconductor device according to one embodiment of the present disclosure includes a first capacitive element, a signal cancellation circuit that generates a first voltage corresponding to a first input voltage in a sampling mode and applies it to one end of the first capacitive element, and holds the generated first voltage in a hold mode after the sampling mode while applying it to one end of the first capacitive element, a sampling circuit that samples the first input voltage in the sampling mode and holds a second voltage corresponding to the sampled first input voltage in the hold mode while applying it to the other end of the first capacitive element, a negative feedback circuit that generates an output signal corresponding to the voltage at the other end of the first capacitive element in the hold mode and applies a feedback signal corresponding to the output signal to one end of the first capacitive element, a first AD converter that performs AD conversion on the first input voltage, and an addition/subtraction circuit that performs addition/subtraction of the output signal of the negative feedback circuit and the output signal of the first AD converter and outputs the result.

This disclosure can provide a semiconductor device capable of operating accurately by suppressing errors caused by dielectric relaxation phenomena.

### BRIEF DESCRIPTION OF THE DRAWINGS

FIG. 1 is a circuit diagram showing a configuration example of a semiconductor device according to the first embodiment.

FIG. 2 is a timing chart showing the operation of the semiconductor device shown in FIG. 1.

FIG. 3 is a circuit diagram showing the first modified example of the semiconductor device according to the first embodiment.

FIG. 4 is a circuit diagram showing a specific example of the semiconductor device shown in FIG. 3.

FIG. 5 is a circuit diagram showing the second modified example of the semiconductor device according to the first embodiment.

FIG. 6 is a timing chart showing the operation of the semiconductor device shown in FIG. 5.

FIG. 7 is a circuit diagram showing the third modified example of the semiconductor device according to the first embodiment.

FIG. 8 is a circuit diagram showing a configuration example of a semiconductor device according to the second embodiment.

FIG. 9 is a timing chart showing the operation of the semiconductor device shown in FIG. 8.

FIG. 10 is a circuit diagram showing the first modified example of the semiconductor device according to the second embodiment.

FIG. 11 is a circuit diagram showing a specific example of the semiconductor device shown in FIG. 10.

FIG. 12 is a circuit diagram showing the second modified example of the semiconductor device according to the second embodiment.

FIG. 13 is a timing chart showing the operation of the semiconductor device shown in FIG. 12.

FIG. 14 is a circuit diagram showing a configuration example of a semiconductor device according to the third embodiment.

FIG. 15 is a timing chart showing the operation of the semiconductor device shown in FIG. 14.

FIG. 16 is a circuit diagram showing the first modified example of the semiconductor device according to the third embodiment.

FIG. 17 is a circuit diagram showing the first configuration example of a pre-examined semiconductor device.

FIG. 18 is a timing chart showing the operation of the semiconductor device shown in FIG. 17.

FIG. 19 is a diagram showing an equivalent circuit of a capacitive element Cs with a dielectric relaxation phenomenon.

FIG. 20 is a circuit diagram showing the second configuration example of a pre-examined semiconductor device.

FIG. 21 is a timing chart showing the operation of the semiconductor device shown in FIG. 20.

FIG. 22 is a circuit diagram showing the third configuration example of a pre-examined semiconductor device.

FIG. 23 is a timing chart showing the operation of the semiconductor device shown in FIG. 22.

FIG. 24 is a circuit diagram showing the fourth configuration example of a pre-examined semiconductor device.

FIG. 25 is a timing chart showing the operation of the semiconductor device shown in FIG. 24.

### DETAILED DESCRIPTION

Hereinafter, embodiments will be described with reference to the drawings. Note that the drawings are simplified, and therefore, the technical scope of the embodiments should not be narrowly interpreted based on the descriptions in the drawings. Also, the same elements are denoted by the same symbols, and redundant descriptions are omitted.

In the following embodiments, for convenience, when necessary, the description is divided into multiple sections or embodiments. However, unless specifically stated, they are not unrelated to each other, and one may be a modified example, application example, detailed description, supplementary explanation, etc., of all or part of the other. Also, in the following embodiments, when referring to the number of elements, etc. (including the number of elements, numerical values, quantities, ranges, etc.), it is not limited to the specific number, but may be not less than or equal to the specific number, except for cases where the number is specifically indicated and is clearly limited to the specific number in principle.

Furthermore, in the following embodiments, the constituent elements (including the operation steps and the like) are not necessarily essential except in the case where they are specifically specified and the case where they are considered to be obviously essential in principle. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above-mentioned numbers and the like, including the number, the numerical value, the amount, the range, and the like.

### <Preliminary Study By Inventors, Etc.>

Before describing the semiconductor device according to the present embodiment, a semiconductor device that the inventors, etc., have preliminarily studied will be described.

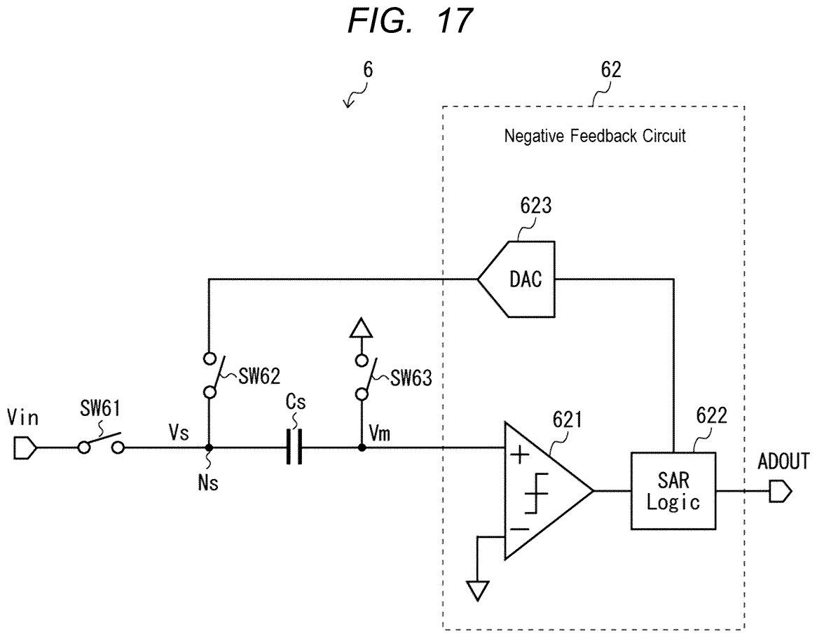

FIG. 17 is a circuit diagram showing a configuration example of the preliminarily studied semiconductor device 6. The semiconductor device 6 is a so-called single-input charge redistribution type sequential comparison type AD converter, which uses a binary search algorithm to convert an analog input voltage Vin into a digital output signal ADOUT and outputs it.

Specifically, the semiconductor device 6 includes a negative feedback circuit 62, a capacitive element Cs, and switches SW61 to SW63. The negative feedback circuit 62 includes a comparator 621, a sequential comparison register circuit (SAR Logic) 622, and a DA converter 623.

The capacitive element Cs is provided between the non-inverting input terminal of the comparator 621 and a node Ns. The switch SW61 is provided between an input terminal (hereinafter referred to as the input terminal Vin) where the input voltage Vin is supplied from outside the semiconductor device 6, and the node Ns (one end of the capacitive element Cs). The switch SW63 is provided between the non-inverting input terminal (the other end of the capacitive element Cs) of the comparator 621 and a reference voltage terminal (hereinafter referred to as the reference voltage terminal Vss) where the reference voltage Vss is supplied. The reference voltage Vss is supplied to the inverting input terminal of the comparator 621.

The sequential comparison register circuit 622 outputs a digital signal (a control signal for controlling the switches of the DA converter 623) according to the comparison result of the comparator 621, and also outputs an output signal ADOUT of the determined digital value. The DA converter 623 converts the digital signal output from the sequential comparison register circuit 622 into an analog voltage and outputs it. The switch SW62 is provided between the output of the DA converter 623 and the node Ns.

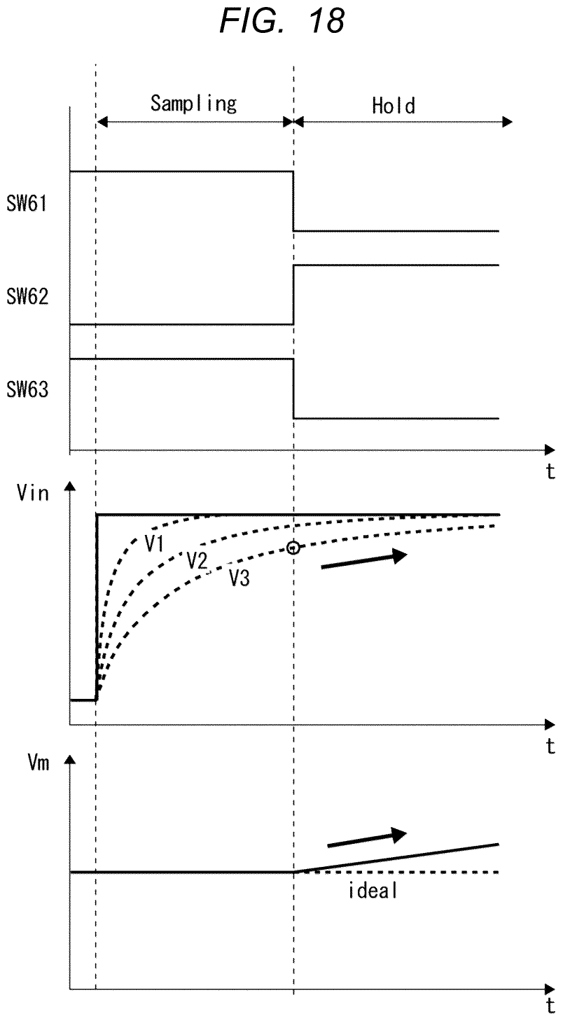

FIG. 18 is a timing chart showing the operation of the semiconductor device 6. Note that each switch is turned off by a low-level control signal and turned on by a high-level control signal. Also, the operation modes of the semiconductor device 6 include at least a sampling mode and a hold mode.

As illustrated in FIG. 18, initially, in the sampling mode, switch SW61 indicates an on state, switch SW62 indicates an off state, and switch SW63 indicates an on state. Accordingly, the input voltage Vin is sampled. In other words, a charge corresponding to the input voltage Vin is accumulated at the node Ns (one end of the capacitive element Cs). As a result, the voltage Vs of the node Ns ideally indicates the input voltage Vin. Subsequently, in the hold mode, the switch SW61 switches from on to off, the switch SW62 switches from off to on, and the switch SW63 switches from on to off. As a result, the sampled input voltage Vin is held in the capacitive element Cs.

At this time, the negative feedback circuit 62 generates an analog voltage such that the voltage Vm at the non-inverting input terminal of the comparator 621 indicates the reference voltage Vss, that is, the voltage Vdac at the node Ndac indicates the input voltage Vin, and outputs it to the node Ndac.

Specifically, the negative feedback circuit 62 performs a sequential comparison operation between the output voltage of the DA converter 623 and the input voltage Vin using the comparator 621 and the sequential comparison register circuit 622. The semiconductor device 6 outputs the output signal ADOUT of the digital value determined in the negative feedback circuit 62.

However, the semiconductor device 6 had a problem that it could not operate accurately due to an AD conversion error caused by the dielectric relaxation phenomenon.

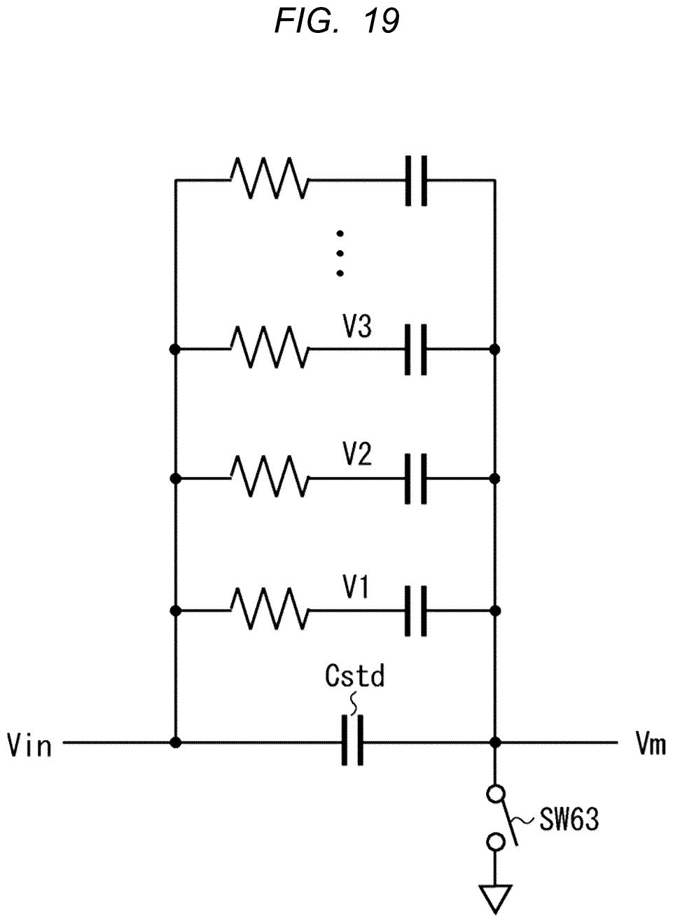

FIG. 19 is a diagram showing an equivalent circuit of a capacitive element Cs having a dielectric relaxation phenomenon. As shown in FIG. 19, a plurality of series circuits composed of parasitic resistance and parasitic capacitance are connected in parallel to the capacitive element Cs in addition to the true capacitance Cstd. It is known that the time constants of each of these multiple series circuits are different from each other and are a distributed constant model with a wide frequency band.

Therefore, in the semiconductor device 6, for example, as shown in FIG. 18, there is a possibility that the operation mode may switch from the sampling mode to the hold mode in a state where the input voltage Vin has not reached the ideal level (solid line) (dotted line). As a result, the voltage Vm at the non-inverting input terminal (the other end of the capacitive element Cs) of the comparator 621 may fluctuate in the hold mode, and as a result, the semiconductor device 6 may not be able to perform AD conversion processing accurately.

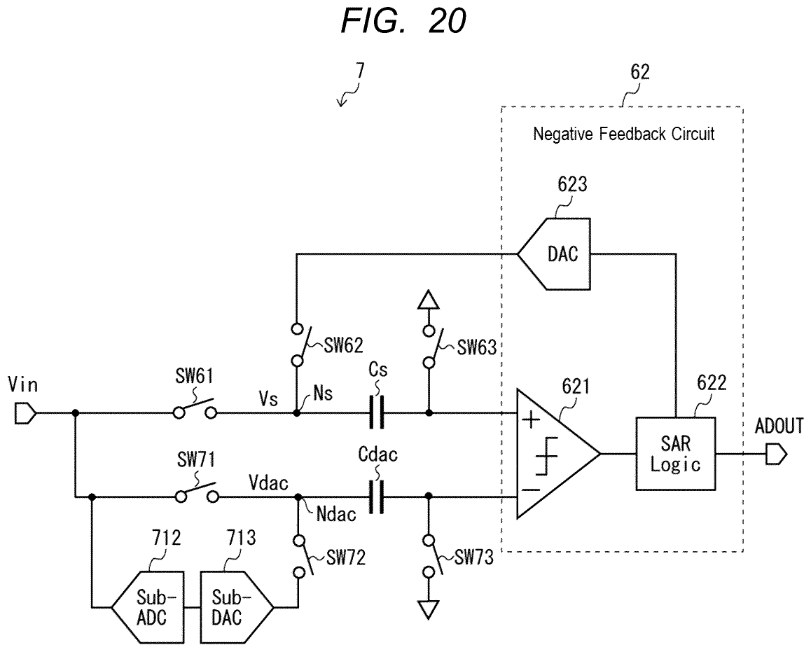

Therefore, the inventors considered the semiconductor device 7 next. FIG. 20 is a circuit diagram showing a configuration example of the semiconductor device 7 that has been preliminarily examined. The semiconductor device 7 further includes a sub AD converter 712, a sub DA converter 713, a capacitive element Cdac, and switches SW71 to SW73, compared to the semiconductor device 6.

The capacitive element Cdac has the same capacitance value as the capacitive element Cs and is provided between the inverting input terminal of the comparator 621 and the node Ndac. The switch SW71 is provided between the input terminal Vin and the node Ndac (one end of the capacitive element Cdac). The switch SW73 is provided between the inverting input terminal (the other end of the capacitive element Cdac) of the comparator 621 and the reference voltage terminal. The sub AD converter 712 and the sub DA converter 713 are provided in parallel with the switch SW71 between the input terminal Vin and the node Ndac. The AD converter 712 converts the analog input voltage Vin into a digital signal and outputs it. The DA converter 713 converts the digital signal output from the AD converter 712 into an analog voltage and outputs it. The switch SW72 is provided between the output of the DA converter 713 and the node Ndac.

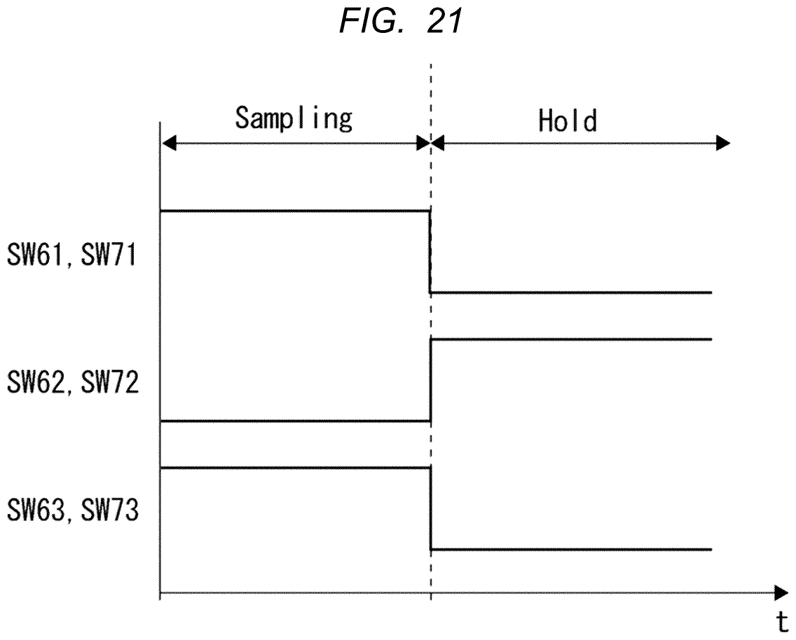

FIG. 21 is a timing chart showing the operation of the semiconductor device 7. Each switch is assumed to turn off by a low-level control signal and turn on by a high-level control signal. The operation mode of the semiconductor device 7 includes at least a sampling mode and a hold mode.

As shown in FIG. 21, first, in the sampling mode, switches SW61 and SW71 indicate an on state, switches SW62 and SW72 indicate an off state, and switches SW63 and SW73 indicate an on state. As a result, the input voltage Vin is sampled. That is, a charge corresponding to the input voltage Vin is accumulated at the node Ns (one end of the capacitive element Cs). Also, a charge corresponding to the input voltage Vin is accumulated at the node Ndac (one end of the capacitive element Cdac). As a result, the voltage Vs at the node Ns ideally indicates the input voltage Vin. Also, the voltage Vdac at the node Ndac ideally indicates the input voltage Vin. Subsequently, in the hold mode, switches SW61 and SW71 switch from on to off, switches SW62 and SW72 switch from off to on, and switches SW63 and SW73 switch from on to off. As a result, the sampled input voltage Vin is held in the capacitive element Cs. Also, the sampled input voltage Vin is held in the capacitive element Cdac. Strictly speaking, it is desirable to have a sequence in which switch SW71 switches from on to off, switch SW72 switches from off to on, then switches SW63 and SW73 switch from on to off, and then switch SW61 switches from on to off, and switch SW62 switches from off to on. This is because it can eliminate the effects of errors in the AD converter 712 and the DA converter 713. However, this strict timing operation is not necessary when considering the effects of dielectric relaxation.

At this time, the negative feedback circuit 62 generates an analog voltage, that is, an analog voltage that makes the node Ndac indicate the input voltage Vin, so that the non-inverting input terminal of the comparator 621 indicates the same voltage value as the inverting power terminal, and outputs it to the node Ndac.

Specifically, the negative feedback circuit 62 performs a sequential comparison operation of the output voltage of the DA converter 623 and the input voltage Vin using the comparator 621 and the sequential comparison register circuit 622. Then, the semiconductor device 7 outputs the output signal ADOUT of the digital value determined in the negative feedback circuit 62.

Here, in the semiconductor device 7, an error of the input voltage Vin due to the dielectric relaxation phenomenon occurs in each of the capacitive elements Cs and Cdac. Therefore, in the semiconductor device 7, the comparator 621 can compare these error components and cancel them. That is, the semiconductor device 7 can suppress the error of AD conversion caused by the dielectric relaxation phenomenon and operate with high accuracy.

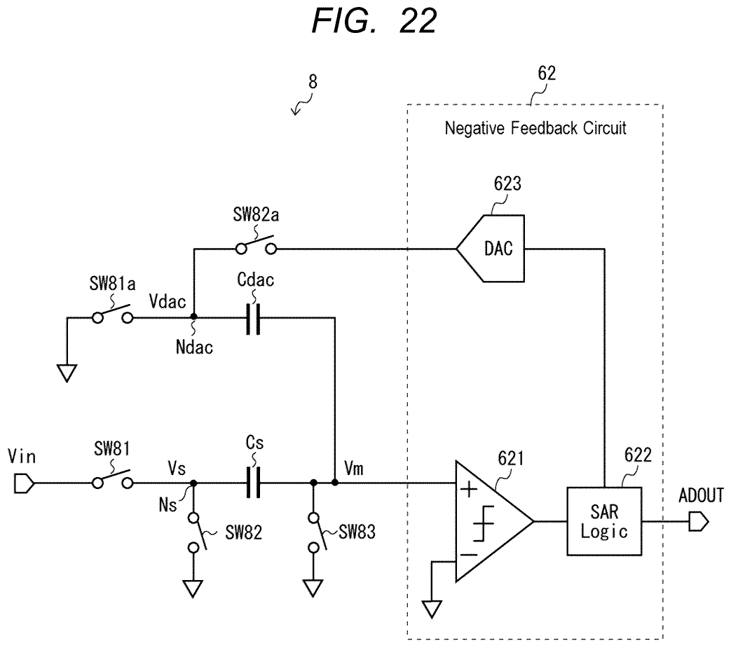

In recent years, not only the semiconductor device 7, which is a sequential comparison type AD conversion circuit of the charge redistribution type, but also an AD conversion circuit in which a sampling capacitive element and a DA conversion capacitive element are separated, and a top plate sampling type AD conversion circuit, etc., are required to suppress errors caused by the dielectric relaxation phenomenon and operate with high accuracy. This will be briefly explained using FIGS. 22-25.

FIG. 22 is a circuit diagram showing a configuration example of a semiconductor device 8 that has been studied in advance. The semiconductor device 8 is an AD converter in which a sampling capacitive element and a DA conversion capacitive element are separated.

Specifically, the semiconductor device 8, compared to the semiconductor device 6, further includes the capacitive element Cdac in addition to the capacitive element Cs, and includes switches SW81, SW81a, SW82, SW82a, and SW83 instead of switches SW61 to SW63.

The capacitive element Cs is provided between the non-inverting input terminal of the comparator 621 and the node Ns. The switch SW81 is provided between the input terminal Vin and the node Ns (one end of the capacitive element Cs). The switch SW82 is provided between the node Ns and the reference voltage terminal Vss. The capacitive element Cdac is provided between the non-inverting input terminal of the comparator 621 and the node Ndac. The switch SW81a is provided between the reference voltage terminal Vss and the node Ndac (one end of the capacitive element Cdac). The switch SW82a is provided between the output of the DA converter 623 and the node Ndac. The switch SW83 is provided between the non-inverting input terminal of the comparator 621 and the reference voltage terminal Vss.

The other configurations of the semiconductor device 8 are the same as those of the semiconductor device 6, so their descriptions are omitted.

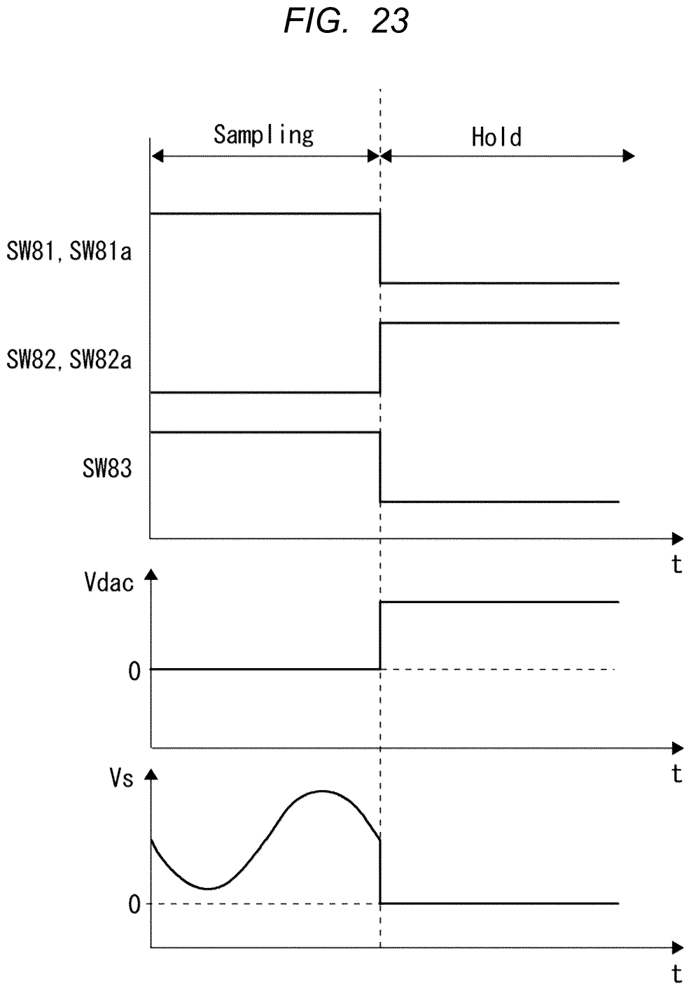

FIG. 23 is a timing chart showing the operation of the semiconductor device 8. Each switch is assumed to turn off by a low-level control signal and turn on by a high-level control signal. Furthermore, the operation modes of the semiconductor device 8 include at least a sampling mode and a hold mode.

As shown in FIG. 23, first, in the sampling mode, the switches SW81, SW81a indicate an on state, the switches SW82, SW82a indicate an off state, and the switch SW83 indicates an on state. As a result, the input voltage Vin is sampled. That is, a charge corresponding to the input voltage Vin is accumulated at the node Ns (one end of the capacitive element Cs). As a result, the voltage Vs at the node Ns ideally indicates the input voltage Vin. Also, at this time, the voltage Vdac at the node Ndac indicates the reference voltage Vss.

Then, in the hold mode, the switches SW81, SW81a switch from on to off, the switches SW82, SW82a switch from off to on, and the switch SW83 switches from on to off. As a result, the sampled input voltage Vin is held in the capacitive element Cs. Here, when the voltage Vs at the node Ns transitions from the input voltage Vin to the reference voltage Vss by turning on the switch SW82, the negative feedback circuit 62 generates an analog voltage that makes the voltage Vm at the non-inverting input terminal of the comparator 621 indicate the reference voltage Vss, that is, an analog voltage that makes the voltage Vdac at the node Ndac indicate the input voltage Vin, and outputs it to the node Ndac.

Specifically, the negative feedback circuit 62 performs a sequential comparison operation between the output voltage of the DA converter 623 and the input voltage Vin using the comparator 621 and the sequential comparison register circuit 622. Then, the semiconductor device 8 outputs the output signal ADOUT of the digital value determined in the negative feedback circuit 62.

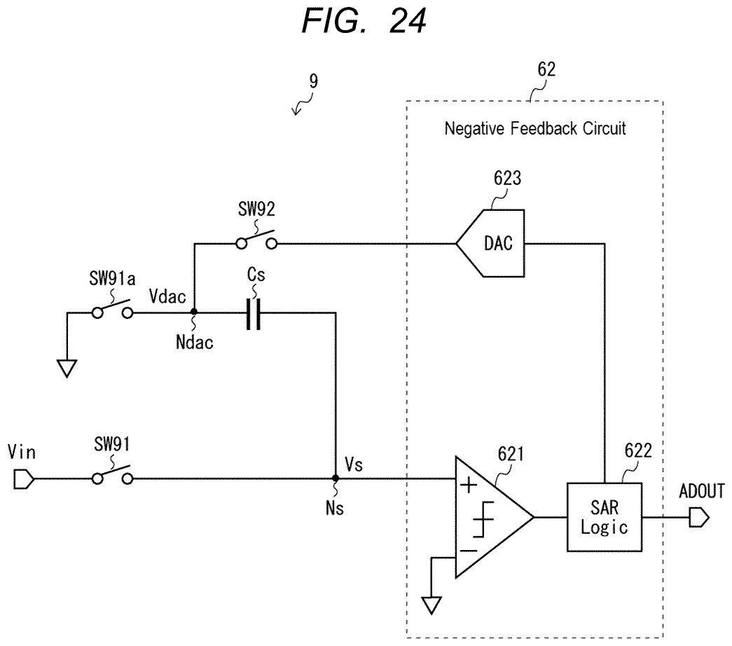

FIG. 24 is a circuit diagram showing a configuration example of a pre-examined semiconductor device 9. The semiconductor device 9 is a so-called top-plate sampling type AD converter.

Specifically, the semiconductor device 9 is equipped with switches SW91, SW91a, SW92 instead of switches SW61 to SW63 compared to the semiconductor device 6.

The switch SW91 is provided between the non-inverting input terminal (node Ns) of the comparator 621 and the input terminal Vin. The capacitive element Cs is provided between the non-inverting input terminal of the comparator 621 and the node Ndac. The switch SW91a is provided between the node Ndac (one end of the capacitive element Cs) and the input terminal Vin. The switch SW92 is provided between the output of the DA converter 623 and the node Ndac.

The other configurations of the semiconductor device 9 are the same as those of the semiconductor device 6, so their descriptions are omitted.

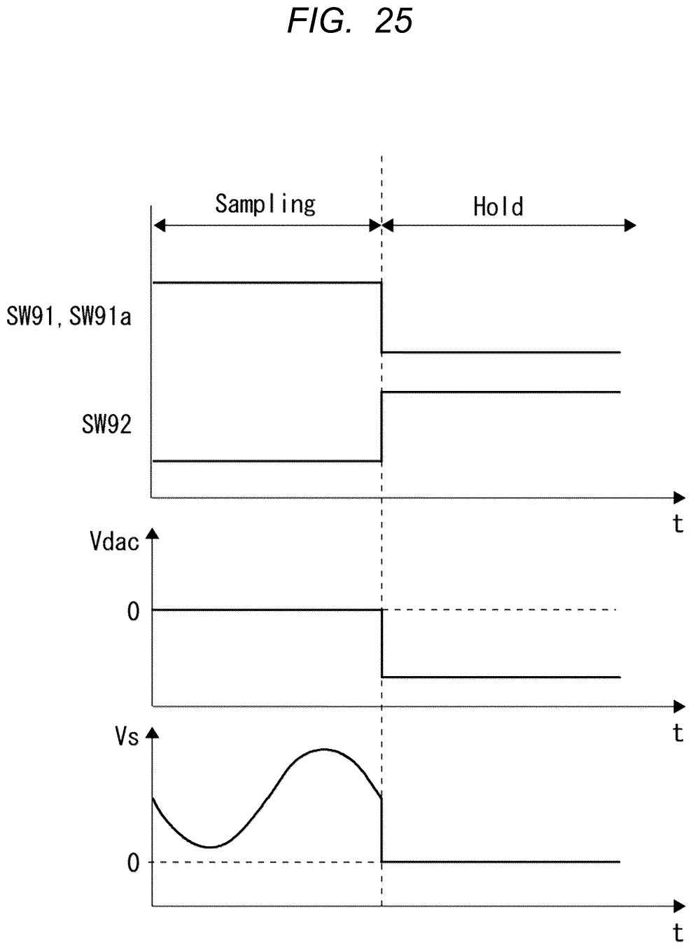

FIG. 25 is a timing chart showing the operation of the semiconductor device 9. Each switch is assumed to turn off by a low-level control signal and turn on by a high-level control signal. Furthermore, the operation modes of the semiconductor device 9 include at least a sampling mode and a hold mode.

As shown in FIG. 25, first, in the sampling mode, the switches SW91, SW91a indicate an on state, and the switch SW92 indicates an off state. As a result, the input voltage Vin is sampled. That is, a charge corresponding to the input voltage Vin is accumulated at the non-inverting input terminal of the comparator 621. As a result, the voltage Vs at the non-inverting input terminal of the comparator 621 ideally indicates the input voltage Vin. Also, at this time, the voltage Vdac at the node Ndac indicates the reference voltage Vss.

Subsequently, in the hold mode, switches SW91 and SW91a switch from on to off, and switch SW92 switches from off to on. As a result, the sampled input voltage Vin is held in the capacitor element Cs. At this time, the negative feedback circuit 62 generates an analog voltage such that the non-inverting input terminal of the comparator 621 indicates the reference voltage Vss, that is, the node Ndac indicates-Vin, and outputs it to the node Ndac.

Specifically, the negative feedback circuit 62 performs a successive comparison operation between the output voltage of the DA converter 623 and the input voltage Vin using the comparator 621 and the successive comparison register circuit 622. Then, the semiconductor device 9 outputs the output signal ADOUT of the digital value determined in the negative feedback circuit 62.

In recent years, not only the semiconductor device 7, which is a successive comparison type AD conversion circuit of charge redistribution type, but also the semiconductor device 8, which is an AD conversion circuit where the sampling capacitor and the DA conversion capacitor are separated, and the semiconductor device 9, which is a top plate sampling type AD conversion circuit, are required to suppress errors caused by dielectric relaxation phenomena and operate accurately. Therefore, a semiconductor device 1 capable of suppressing errors caused by dielectric relaxation phenomena and operating accurately has been found.

### FIRST EMBODIMENT

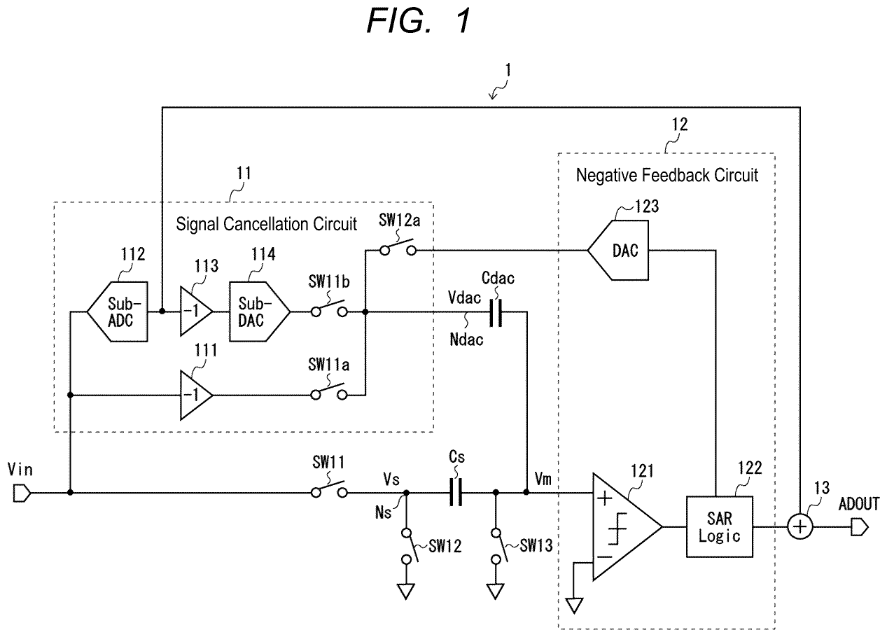

FIG. 1 is a circuit diagram showing a configuration example of the semiconductor device 1 according to the first embodiment. The semiconductor device 1 is an AD converter in which the sampling capacitor and the DA conversion capacitor are separated, and converts the analog input voltage Vin into a digital output signal ADOUT and outputs it.

Specifically, the semiconductor device 1 includes a signal cancellation circuit 11, a negative feedback circuit 12, an addition circuit 13, capacitor elements Cs, Cdac, and switches SW11 to SW13. The signal cancellation circuit 11 includes an inversion circuit 111, a sub AD converter 112, an inversion circuit 113, a sub DA converter 114, switches SW11a, SW11b, and a switch SW12a. The negative feedback circuit 12 includes a comparator 121, a successive comparison register circuit 122, and a DA converter 123. For example, the switches SW11 to SW13 and the capacitor element Cs constitute a sampling circuit.

The capacitor element Cs is provided between the non-inverting input terminal of the comparator 121 and the node Ns. The switch SW11 is provided between the input terminal Vin and the node Ns (one end of the capacitor element Cs). The switch SW12 is provided between the node Ns and the reference voltage terminal Vss. The switch SW13 is provided between the non-inverting input terminal of the comparator 121 and the reference voltage terminal Vss. The reference voltage Vss is supplied to the inverting input terminal of the comparator 121.

The capacitor element Cdac has the same capacitance value as the capacitor element Cs and is provided between the non-inverting input terminal of the comparator 121 and the node Ndac. The signal cancellation circuit 11 is provided between the input terminal Vin and the node Ndac (one end of the capacitor element Cdac).

In the signal cancellation circuit 11, the inversion circuit 111 inverts the input voltage Vin and outputs it. Here, in the inversion of the inversion circuit 111, if the input of the inversion circuit 111 is x, the output of the inversion circuit 111 is y, and the common potential inverted by the inversion circuit 111 is Vcm1, the relationship y=−(x−Vcm1)+Vcm1 holds. Hereinafter, the voltage inversion by each inversion circuit means the relationship of the above formula.

The AD converter 112, the inversion circuit 113, and the DA converter 114 are provided on a path different from the inversion circuit 111 among the paths between the input terminal Vin and the node Ndac. The AD converter 112 converts the sampled input voltage Vin into a digital signal and outputs it. The inversion circuit 113 inverts the output signal of the AD converter 112 and outputs it. The DA converter 114 converts the output signal of the inverting circuit 113 into an analog voltage and outputs it.

In the present embodiment, an example where the gain of each inverting circuit 111, 113 is −1 will be explained. However, if the capacitance value of the capacitive element Cdac is Cdac and the capacitance value of the capacitive element Cs is Cs, and the capacitive element Cdac is configured to indicate a capacitance value that satisfies Cdac=Cs/k, the gain of each inverting circuit 111, 113 may be −k.

The switch SW11a is provided between the output of the inverting circuit 111 and the node Ndac. The switch SW11b is provided between the output of the DA converter 114 and the node Ndac. The switches SW11a and SW11b function as a selection circuit that selects and outputs either the output of the inverting circuit 111 or the output of the DA converter 114.

The successive comparison register circuit 122 outputs a digital signal (a control signal for controlling the switch of the DA converter 123) according to the comparison result of the comparator 121, and also outputs an output signal of a determined digital value. The DA converter 123 converts the digital signal output from the successive comparison register circuit 122 into an analog voltage and outputs it. The switch SW12a is provided between the output of the DA converter 123 and the node Ndac.

The adder circuit 13 adds the output of the AD converter 112 and the output of the successive comparison register circuit 122, and outputs the addition result as a digital output signal ADOUT.

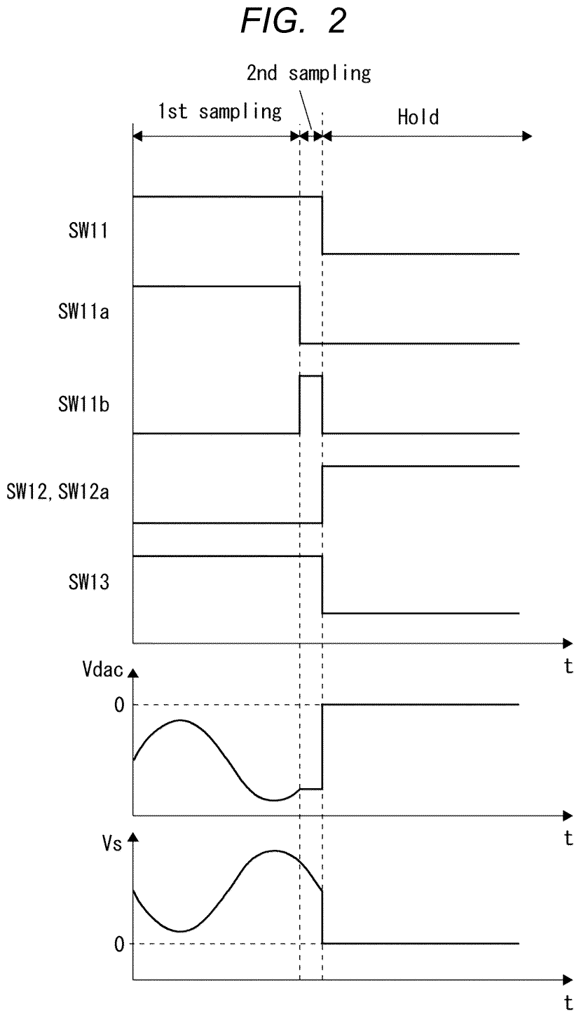

FIG. 2 is a timing chart showing the operation of the semiconductor device 1. Each switch is turned off by a low-level control signal and turned on by a high-level control signal. The operation modes of the semiconductor device 1 include at least a sampling mode and a hold mode. The sampling mode is composed of a first sampling mode and a second sampling mode.

First, in the first sampling mode, the switch SW11 indicates an on state, the switch SW11a indicates an on state, the switch SW11b indicates an off state, the switches SW12, SW12a indicate an off state, and the switch SW13 indicates an on state. As a result, the input voltage Vin is sampled. That is, a charge corresponding to the input voltage Vin is accumulated at the node Ns (one end of the capacitive element Cs). As a result, the voltage Vs at the node Ns ideally indicates the input voltage Vin. Also, at the node Ndac (one end of the capacitive element Cdac), a charge corresponding to the voltage inverted from the input voltage Vin is accumulated. As a result, the voltage Vdac at the node Ndac ideally indicates the voltage Vinx inverted from the input voltage Vin.

Then, in the second sampling mode, the switch SW11a switches from on to off, and the switch SW11b switches from off to on. As a result, the AD converter 112 converts the input voltage Vin, which was sampled and held in the first sampling mode, into a digital signal and outputs it. The inverting circuit 113 inverts the output signal of the AD converter 112 and outputs it. The DA converter 114 converts the output signal of the inverting circuit 113 into an analog voltage and outputs it to the node Ndac.

Then, in the hold mode, the switch SW11 switches from on to off, the switch SW11b switches from on to off, the switches SW12, SW12a switch from off to on, and the switch SW13 switches from on to off. As a result, the sampled input voltage Vin is held in the capacitive element Cs. Also, the sampled output voltage of the DA converter 114 (equivalent to the voltage Vinx) is held in the capacitive element Cdac.

Here, when the switch SW12 is turned on and the voltage Vs of the node Ns transitions from the input voltage Vin to the reference voltage Vss, the negative feedback circuit 12 generates an analog voltage such that the voltage Vm of the non-inverting input terminal of the comparator 121 indicates the reference voltage Vss, that is, the voltage Vdac of the node Ndac transitions from the voltage Vinx to the reference voltage Vss, and outputs it to the node Ndac.

Specifically, the negative feedback circuit 12 performs a sequential comparison operation between the output voltage of the DA converter 123 and the input voltage Vin using the comparator 121 and the sequential comparison register circuit 122.

Here, in the semiconductor device 1, an error occurs in the capacitive element Cs due to the dielectric relaxation phenomenon, and an error of opposite polarity to the error that occurred in the capacitive element Cs occurs in the capacitive element Cdac due to the dielectric relaxation phenomenon. Therefore, at the voltage Vm of the non-inverting input terminal of the comparator 121, where the other ends of the capacitive element Cs and the capacitive element Cdac are commonly connected, these error components are cancelled. However, at the voltage Vm of the non-inverting input terminal of the comparator 121, the component of the input voltage Vin (input signal component) is also cancelled.

Therefore, the semiconductor device 1 uses the addition circuit 13 to add the input signal component (AD conversion result of the input voltage Vin) output from the AD converter 112 and the signal component that was not cancelled by the signal cancellation circuit 11 output from the sequential comparison register circuit 122, and outputs the addition result as a digital output signal ADOUT. As a result, the semiconductor device 1 can output a high-precision digital output signal ADOUT with cancelled errors.

In this way, the semiconductor device 1 according to the present embodiment samples the input voltage Vin and the voltage that inverts it, and holds them in the capacitive elements Cs and Cdac, which are commonly connected to the non-inverting input terminal of the comparator 121. As a result, the semiconductor device 1 according to the present embodiment can cancel the error caused by the dielectric relaxation phenomenon and the error of opposite polarity caused by the dielectric relaxation phenomenon, and can accurately capture the input voltage Vin and accurately convert it into a digital output signal ADOUT and output it.

### First Modified Example of Semiconductor Device 1

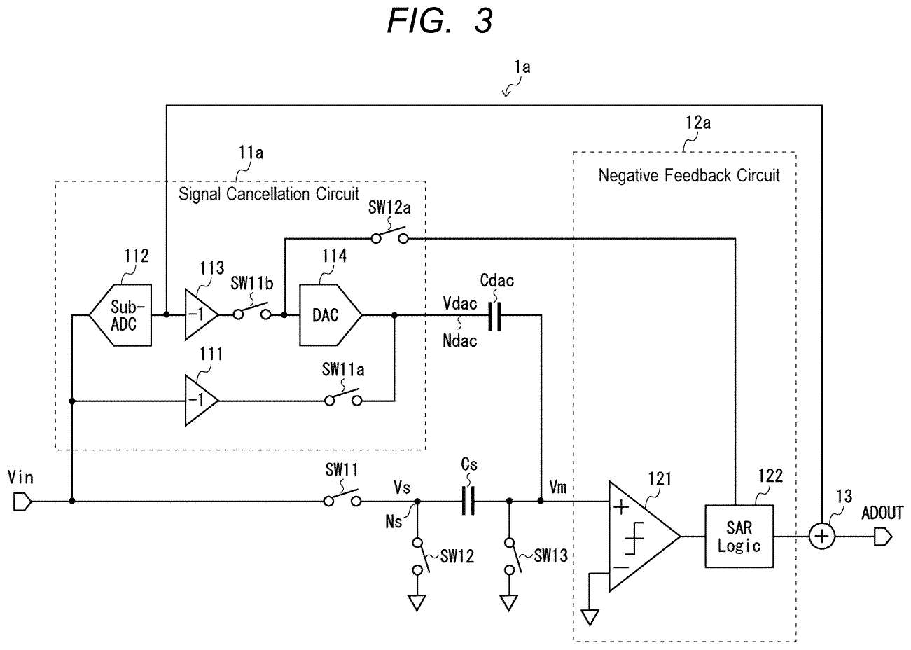

FIG. 3 is a circuit diagram showing a first modified example of the semiconductor device 1 as the semiconductor device 1a. Compared with the semiconductor device 1, the semiconductor device 1a is equipped with a signal cancellation circuit 11a instead of the signal cancellation circuit 11, and a negative feedback circuit 12a instead of the negative feedback circuit 12.

The negative feedback circuit 12a does not include a DA converter 123, and realizes the function of the DA converter 123 using the DA converter 114. In other words, the DA converter 114 can also be used as the DA converter 123. In the signal cancellation circuit 11a, the switch SW12a is provided between the output of the sequential comparison register circuit 122 and the input of the DA converter 114. The other configurations of the semiconductor device 1a are the same as those of the semiconductor device 1, so their descriptions are omitted.

The semiconductor device 1a can achieve the same level of effect as the semiconductor device 1. Furthermore, the semiconductor device 1a can reduce the number of DA converters compared to the semiconductor device 1, thereby reducing the circuit scale.

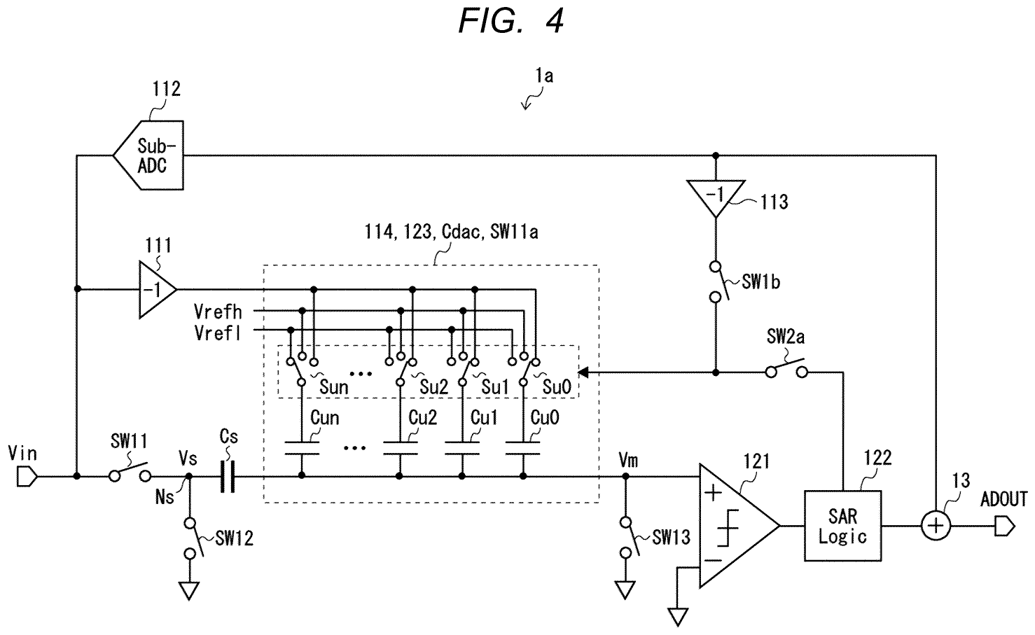

Next, a specific configuration example of the semiconductor device 1a will be described using FIG. 4. FIG. 4 is a circuit diagram showing a specific example of the semiconductor device 1a.

In the example of FIG. 4, the DA converter 114 includes a capacitance element Cu0, Cu1 indicating the minimum capacitance value 2\hat{ }0·C, n−1 (n is an integer of 2 or more) capacitance elements Cu2 to Cun binary-weighted with respect to the capacitance value of the capacitance element Cu1, and switches Su0, Su1 to Sun provided corresponding to each of the capacitance elements Cu0, Cu1 to Cun. Here, the switches Su0, Su1 to Sun are not only used as part of the DA converter 114, but also used as the switch SW11a. The capacitance elements Cu0, Cu1 to Cun are not only used as part of the DA converter 114, but also used as the capacitance element Cdac. In addition, the DA converter 114 can also be used as the DA converter 123 provided in the negative feedback circuit 12 of the semiconductor device 1.

### Second Modified Example of Semiconductor Device 1

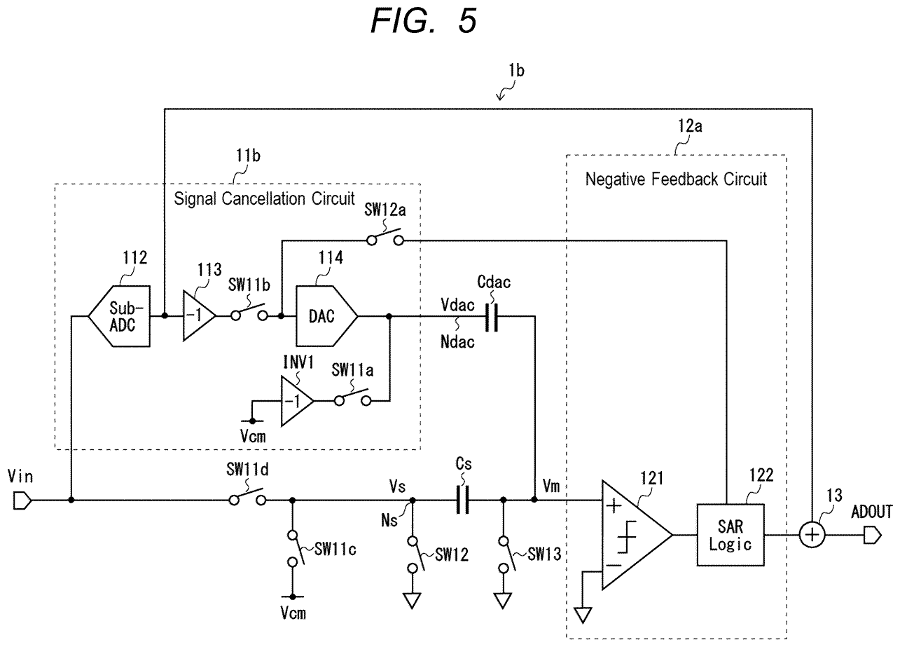

FIG. 5 is a circuit diagram showing the second modified example of the semiconductor device 1 as the semiconductor device 1b. The semiconductor device 1b, compared to the semiconductor device 1a, includes a signal cancellation circuit 11b instead of the signal cancellation circuit 11a, and switches SW11c, SW11d instead of the switch SW11.

The signal cancellation circuit 11b does not include an inversion circuit 111 compared to the signal cancellation circuit 11a. And the switch SW11a is provided between the node Ndac and the inversion circuit INV1 that generates the inverted voltage of the common voltage Vcm.

The switch SW11c is provided between the node Ns and the voltage supply terminal (hereinafter referred to as the voltage supply terminal Vcm) to which the common voltage Vcm is supplied. The switch SW11d is provided between the input terminal Vin and the node Ns. In other words, the switch SW11d is provided where the switch SW11 was provided.

The other configurations of the semiconductor device 1b are the same as those of the semiconductor device 1a, so their descriptions are omitted.

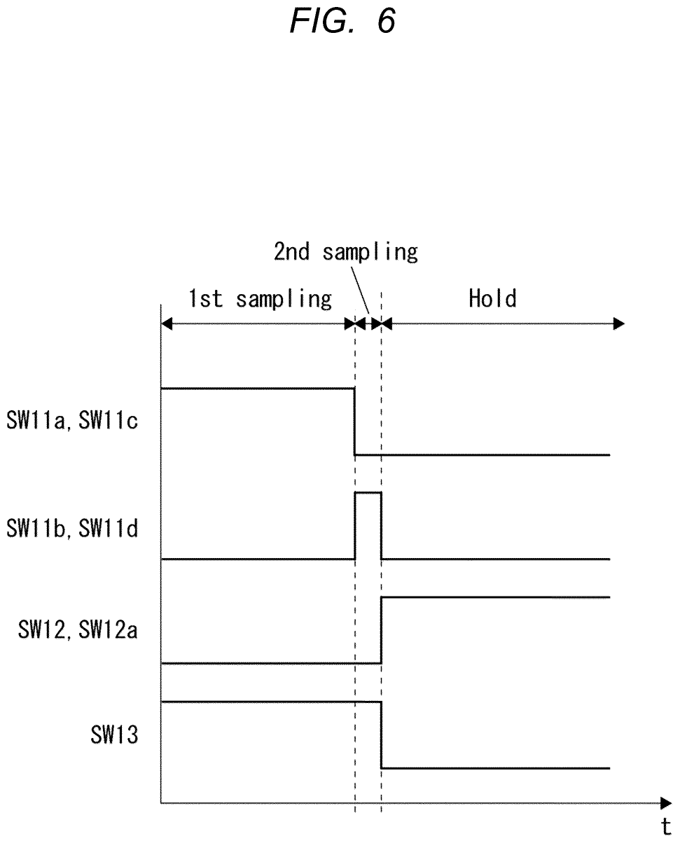

FIG. 6 is a timing chart showing the operation of the semiconductor device 1b. Each switch is assumed to turn off by a low-level control signal and turn on by a high-level control signal. The operation modes of the semiconductor device 1b include at least a sampling mode and a hold mode. The sampling mode is composed of a first sampling mode and a second sampling mode.

First, in the first sampling mode, the switches SW11a, SW11c indicate an on state, the switches SW11b, SW11d indicate an off state, the switches SW12, SW12a indicate an off state, and the switch SW13 indicates an on state. As a result, charges corresponding to the common voltage Vcm and the inverted voltage of the common voltage Vcm are accumulated at the node Ns (one end of the capacitance element Cs) and the node Ndac (one end of the capacitance element Cdac), respectively. As a result, the voltage Vs of the node Ns and the voltage Vdac of the node Ndac each indicate the common voltage Vcm and the inverted voltage of the common voltage Vcm.

Then, in the second sampling mode, the switches SW11a, SW11c switch from on to off, and the switches SW11b, SW11d switch from off to on. As a result, the input voltage Vin is sampled. In other words, a charge corresponding to the input voltage Vin is accumulated at the node Ns (one end of the capacitor Cs). As a result, the voltage Vs of the node Ns ideally indicates the input voltage Vin.

Also, in the second sampling mode, the AD converter 112 converts the input voltage Vin, which was sampled and held in the first sampling mode, into a digital signal and outputs it. The inverting circuit 113 inverts the output signal of the AD converter 112 and outputs it. The DA converter 114 converts the output signal of the inverting circuit 113 into an analog voltage and outputs it to the node Ndac. As a result, the voltage Vdac of the node Ndac ideally indicates the voltage Vinx, which is the inverted input voltage Vin.

Subsequently, in the hold mode, the switches SW11b and SW11d switch from on to off, the switches SW12 and SW12a switch from off to on, and the switch SW13 switches from on to off. As a result, the sampled input voltage Vin is held in the capacitor Cs, and the voltage Vinx, which is the inverted sampled input voltage Vin, is held in the capacitor Cdac.

Here, when the voltage Vs of the node Ns transitions to the reference voltage Vss by turning on the switch SW12, the negative feedback circuit 12 generates an analog voltage such that the voltage Vm of the non-inverting input terminal of the comparator 121 indicates the reference voltage Vss, i.e., the voltage Vdac of the node Ndac transitions from the voltage Vinx to the reference voltage Vss, and outputs it to the node Ndac.

Specifically, the negative feedback circuit 12 performs a sequential comparison operation between the output voltage of the DA converter 123 and the input voltage Vin using the comparator 121 and the sequential comparison register circuit 122.

Here, in the semiconductor device 1b, an error occurs in the capacitor Cs due to the dielectric relaxation phenomenon, and an error of the opposite polarity occurs in the capacitor Cdac due to the dielectric relaxation phenomenon. Therefore, at the voltage Vm of the non-inverting input terminal of the comparator 121, which is commonly connected to the other ends of the capacitor Cs and the capacitor Cdac, these error components are cancelled. However, at the voltage Vm of the non-inverting input terminal of the comparator 121, the component of the input voltage Vin (input signal component) is also cancelled.

Therefore, the semiconductor device 1b uses the adder circuit 13 to add the input signal component (the AD conversion result of the input voltage Vin) output from the AD converter 112 and the signal component that was not cancelled by the signal cancellation circuit 11b and output from the sequential comparison register circuit 122, and outputs the addition result as a digital output signal ADOUT. As a result, the semiconductor device 1b can output a high-accuracy digital output signal ADOUT with cancelled errors.

In this way, the semiconductor device 1b can achieve the same effect as the semiconductor device 1a by applying a common voltage Vcm to the capacitor Cs when the input voltage Vin is not supplied in the first sampling mode, and waiting in a state where the inverted voltage of the common voltage Vcm is applied to the capacitor Cdac. Also, the semiconductor device 1b can achieve the same effect as the semiconductor device 1a by applying the input voltage Vin to the node Ns in the second sampling mode, and applying a voltage equivalent to the input voltage Vin obtained from the output of the signal cancellation circuit to the node Ndac. However, a greater effect can be expected when the input voltage Vin does not change significantly (i.e., the input voltage Vin behaves like a DC) in the second sampling mode.

### Third Modified Example of Semiconductor Device 1

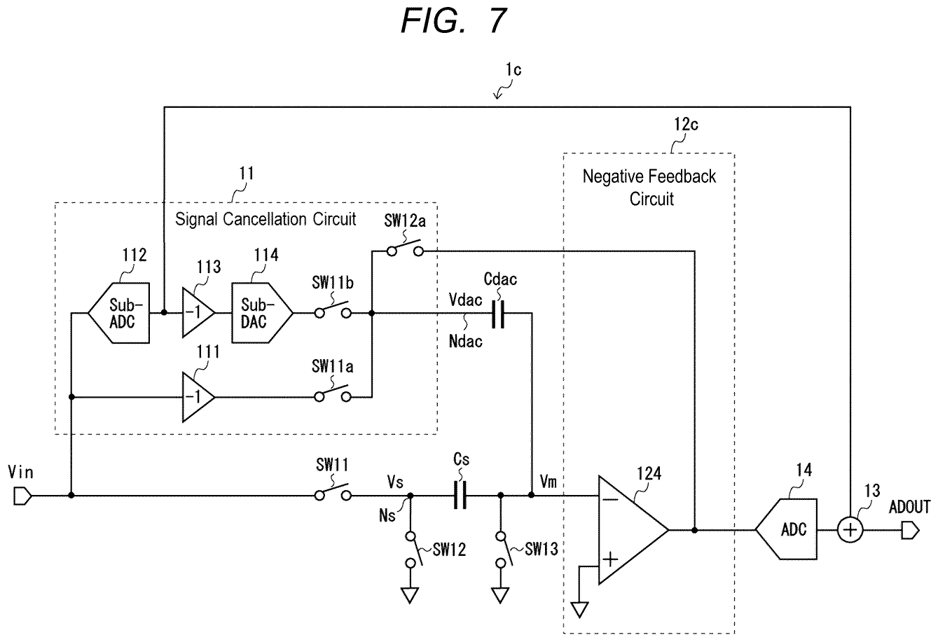

FIG. 7 is a circuit diagram showing the third modified example of the semiconductor device 1 as the semiconductor device 1c. Compared to the semiconductor device 1, the semiconductor device 1c is equipped with a negative feedback circuit 12c instead of the negative feedback circuit 12, and further includes an AD converter 14. The negative feedback circuit 12c includes an operational amplifier 124.

The inverting input terminal of the operational amplifier 124 is connected to the other end of the capacitive element Cs and the other end of the capacitive element Cdac. The non-inverting input terminal of the operational amplifier 124 is supplied with a reference voltage Vss. A switch SW12a is provided between the output of the operational amplifier 124 and the node Ndac (one end of the capacitive element Cdac).

The operational amplifier 124 amplifies the potential difference between the voltage Vm at the inverting input terminal and the voltage Vss at the non-inverting input terminal and outputs it. The output voltage of the operational amplifier 124 is fed back and applied to the node Ndac via the switch SW12a.

The AD converter 14 converts the output voltage of the operational amplifier 124 into a digital signal and outputs it. The adder circuit 13 adds the input signal component (the AD conversion result of the input voltage Vin) output from the AD converter 112 and the signal component that was not cancelled by the signal cancellation circuit 11c and output from the AD converter 14, and outputs the addition result as a digital output signal. As a result, the semiconductor device 1c can output a high-precision digital output signal ADOUT with cancelled errors.

As a result, the semiconductor device 1c can achieve the same level of effect as the semiconductor device 1.

### Second Embodiment

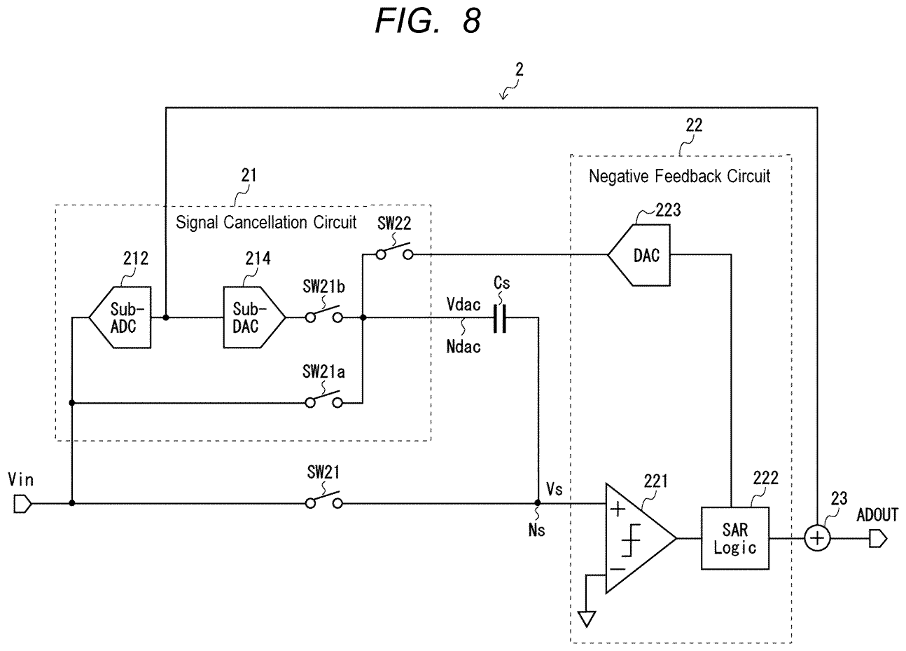

FIG. 8 is a circuit diagram showing a configuration example of a semiconductor device 2 according to the second embodiment. The semiconductor device 2 is a so-called top-plate sampling type AD converter.

Specifically, the semiconductor device 2 includes a signal cancellation circuit 21, a negative feedback circuit 22, an adder circuit 23, a capacitive element Cs, and a switch SW21. The signal cancellation circuit 21 includes a sub AD converter 212, a sub DA converter 214, switches SW21a, SW21b, and a switch SW22. The negative feedback circuit 22 includes a comparator 221, a successive comparison register circuit 222, and a DA converter 223. For example, the switch SW21 constitutes a sampling circuit.

The switch SW21 is provided between the non-inverting input terminal of the comparator 221 and the input terminal Vin. The capacitive element Cs is provided between the non-inverting input terminal of the comparator 221 and the node Ndac. The signal cancellation circuit 21 is provided between the input terminal Vin and the node Ndac (one end of the capacitive element Cs).

In the signal cancellation circuit 21, the switch SW21a is provided on the path between the input terminal Vin and the node Ndac. The AD converter 212, the DA converter 214, and the switch SW21b are provided on a path different from the switch SW21a between the input terminal Vin and the node Ndac. The AD converter 212 samples and holds the input voltage Vin and converts the held input voltage Vin into a digital signal and outputs it. The DA converter 214 converts the output signal of the AD converter 212 into an analog voltage and outputs it. The switches SW21a and SW21b function as a selection circuit that selects and outputs either the input voltage Vin or the DA converter 214.

The successive comparison register circuit 222 outputs a digital signal (a control signal that controls the switch of the DA converter 223) according to the comparison result of the comparator 221, and also outputs an output signal of a determined digital value. The DA converter 223 converts the digital signal output from the successive comparison register circuit 222 into an analog voltage and outputs it.

The switch SW22 is provided between the output of the DA converter 223 and the node Ndac.

The adder circuit 23 adds the output of the AD converter 212 and the output of the successive comparison register circuit 122, and outputs the addition result as a digital output signal ADOUT.

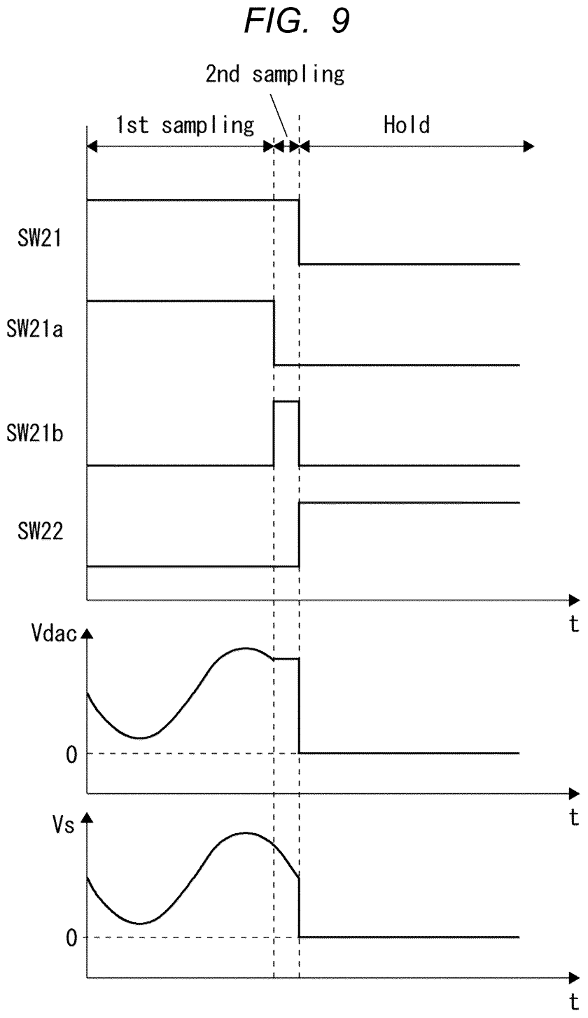

FIG. 9 is a timing chart showing the operation of the semiconductor device 2. Each switch is turned off by a low-level control signal and turned on by a high-level control signal. Furthermore, the operation modes of the semiconductor device 2 include at least a sampling mode and a hold mode. The sampling mode is composed of a first sampling mode and a second sampling mode.

First, in the first sampling mode, the switch SW21 is on, the switch SW21a is on, the switch SW21b is off, and the switch SW22 is off. As a result, the input voltage Vin is sampled. That is, a charge corresponding to the input voltage Vin is accumulated at the node Ns (the other end of the capacitor Cs and the non-inverting input terminal of the comparator 221). As a result, the voltage Vs at the node Ns ideally indicates the input voltage Vin. Also, a charge corresponding to the input voltage Vin is accumulated at the node Ndac (one end of the capacitor Cs). As a result, the voltage Vdac at the node Ndac ideally indicates the input voltage Vin.

Subsequently, in the second sampling mode, the switch SW21a switches from on to off, and the switch SW21b switches from off to on. As a result, the AD converter 212 converts the input voltage Vin, which was sampled and held in the first sampling mode, into a digital signal and outputs it. The DA converter 214 converts the output signal of the AD converter 212 into an analog voltage and outputs it to the node Ndac.

Subsequently, in the hold mode, the switch SW21 switches from on to off, the switch SW21b switches from on to off, and the switch SW22 switches from off to on. As a result, the difference in potential between the sampled input voltage Vin and the output voltage of the signal cancellation circuit 21a is held in the capacitor Cs. At this time, the negative feedback circuit 22 generates an analog voltage such that the voltage Vs at the non-inverting input terminal of the comparator 221 indicates the reference voltage Vss, that is, the voltage Vdac at the node Ndac indicates the reference voltage Vss, and outputs it to the node Ndac.

Specifically, the negative feedback circuit 22 performs a sequential comparison operation between the output voltage of the DA converter 223 and the input voltage Vin using the comparator 221 and the sequential comparison register circuit 222.

Here, in the semiconductor device 2, the voltage Vs at the node Ns, which is one end of the capacitor Cs, and the voltage Vdac at the other end, the node Ndac, behave to cancel each other's signal components. That is, the semiconductor device 2 prevents errors due to dielectric relaxation phenomena by controlling the potential difference between the node Ns and the node Ndac to always be constant. However, the voltage Vm at the non-inverting input terminal of the comparator 221 also cancels the component of the input voltage Vin (input signal component).

Therefore, the semiconductor device 2 uses the adder circuit 23 to add the input signal component (the AD conversion result of the input voltage Vin) output from the AD converter 212 and the signal component that was not cancelled by the signal cancellation circuit 21 output from the sequential comparison register circuit 222, and outputs the sum as the digital output signal ADOUT. As a result, the semiconductor device 2 can output a high-precision digital output signal ADOUT with cancelled errors.

In this way, the semiconductor device 2 according to the present embodiment samples the input voltage Vin and holds it at both ends of the capacitor Cs connected to the non-inverting input terminal of the comparator 221. As a result, the semiconductor device 2 according to the present embodiment can prevent errors due to dielectric relaxation phenomena by cancelling the signal applied to the capacitor Cs, and can accurately capture the input voltage Vin and accurately convert it into a digital output signal ADOUT and output it.

Furthermore, the semiconductor device 2 may use the configuration of the negative feedback circuit 12c having an operational amplifier instead of the negative feedback circuit 22. In that case, the semiconductor device 2 further includes the configuration of the AD converter 14 that performs AD conversion on the output signal of the negative feedback circuit.

### First Modified Example of Semiconductor Device 2

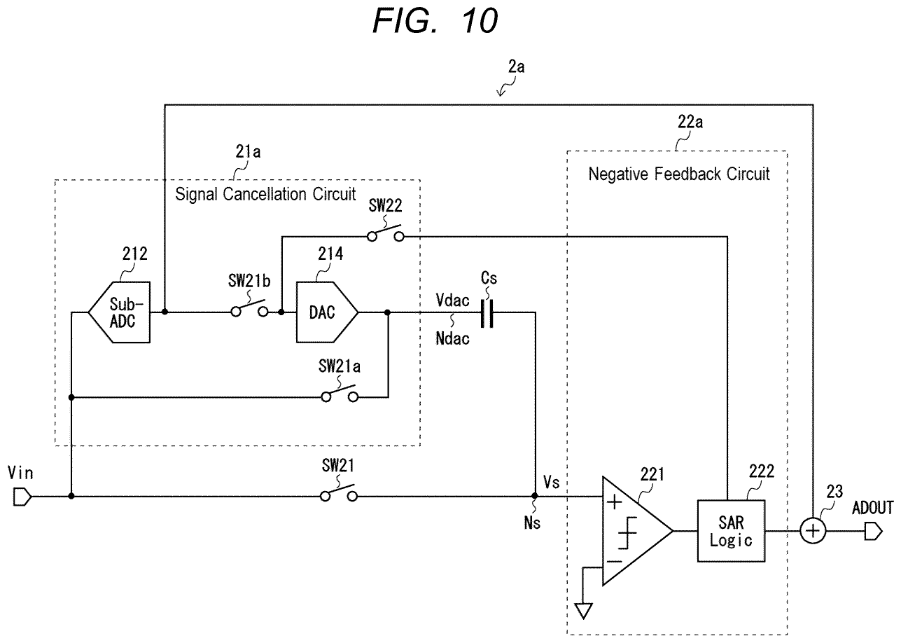

FIG. 10 is a circuit diagram showing the first modified example of the semiconductor device 2 as the semiconductor device 2a. The semiconductor device 2a, compared to the semiconductor device 2, includes the signal cancellation circuit 21a instead of the signal cancellation circuit 21, and the negative feedback circuit 22a instead of the negative feedback circuit 22.

The negative feedback circuit 12a does not include the DA converter 223, and realizes the function of the DA converter 223 using the DA converter 214. In other words, the DA converter 214 can also be used as the DA converter 223. In the signal cancellation circuit 21a, the switch SW22 is provided between the output of the sequential comparison register circuit 222 and the input of the DA converter 214. The other configurations of the semiconductor device 2a are the same as those of the semiconductor device 2, so their description is omitted.

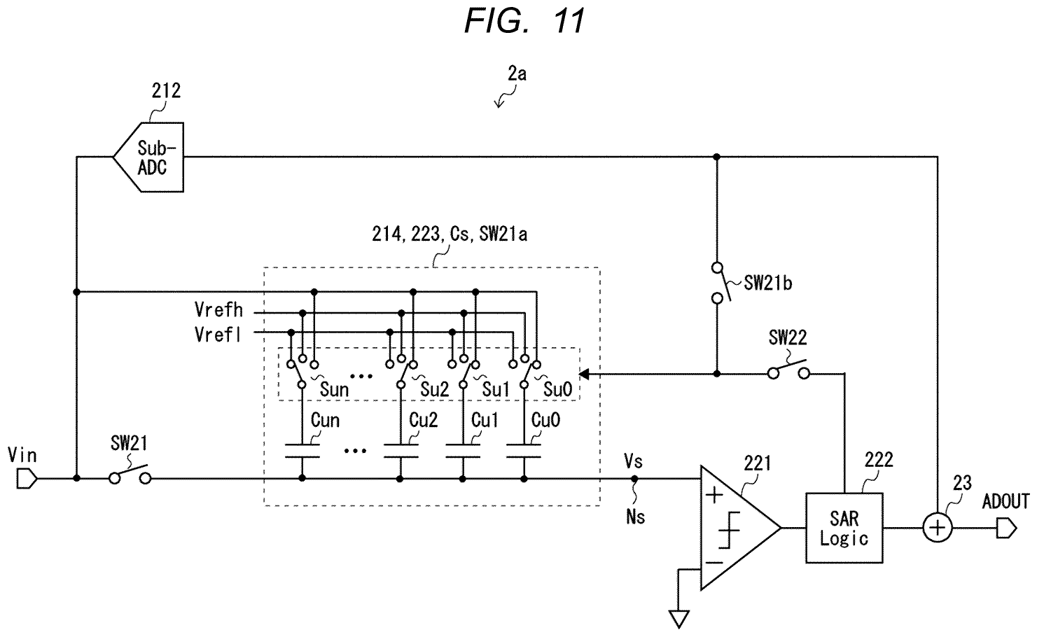

The semiconductor device 2a can achieve an effect equivalent to that of the semiconductor device 2. Furthermore, the semiconductor device 2a can reduce the number of DA converters compared to the semiconductor device 2, thereby reducing the circuit scale. Next, using FIG. 11, a specific configuration example of the semiconductor device 2a will be described. FIG. 11 is a circuit diagram showing a specific example of the semiconductor device 2a.

In the example of FIG. 11, the DA converter 214 includes a capacitance element Cu0, Cu1 indicating the minimum capacitance value 2\hat{ }0·C, n−1 (n is an integer of 2 or more) capacitance elements Cu2 to Cun binary-weighted with respect to the capacitance value of the capacitance element Cu1, and switches Su0, Su1 to Sun provided corresponding to each of the capacitance elements Cu0, Cu1 to Cun. Here, the switches Su0, Su1 to Sun are used not only as part of the DA converter 214 but also as the switch SW21a. The capacitance elements Cu0, Cu1 to Cun are used not only as part of the DA converter 214 but also as the capacitance element Cs. In addition, the DA converter 214 can also be used as the DA converter 223 provided in the negative feedback circuit 22 of the semiconductor device 2.

### Second Modified Example Of Semiconductor Device 2

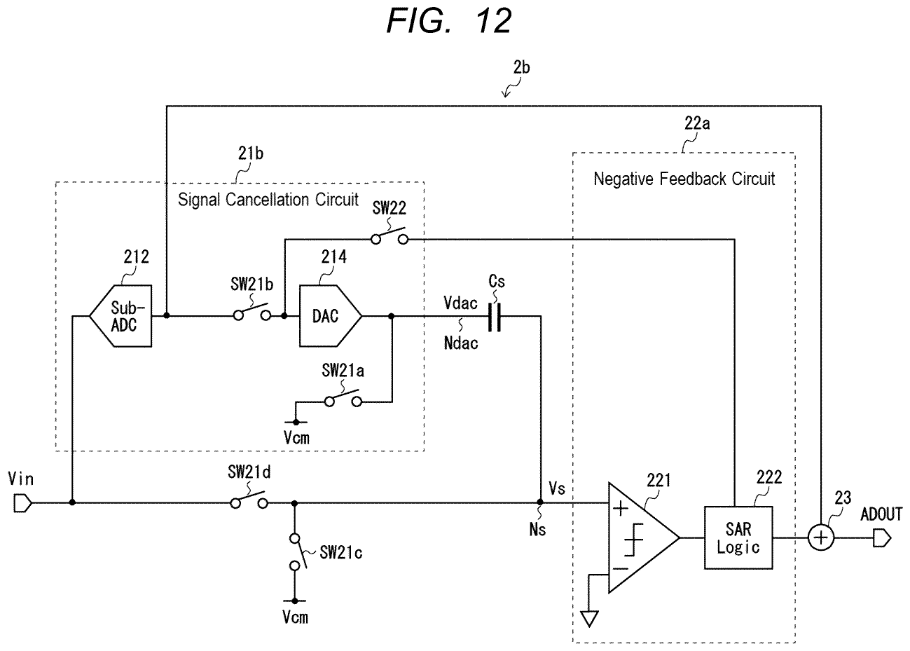

FIG. 12 is a circuit diagram showing the second modified example of the semiconductor device 2 as the semiconductor device 2b. The semiconductor device 2b, compared to the semiconductor device 2a, includes the signal cancellation circuit 21b instead of the signal cancellation circuit 21a, and the switches SW21c, SW21d instead of the switch SW21.

In the signal cancellation circuit 21b, the path of the switch SW21a is different from that of the signal cancellation circuit 21a. The switch SW21a is provided between the node Ndac and the voltage supply terminal Vcm. The switch SW21c is provided between the node Ns and the voltage supply terminal Vcm. The switch SW21d is provided between the input terminal Vin and the node Ns. The other configurations of the semiconductor device 2b are the same as those of the semiconductor device 2a, so their description is omitted.

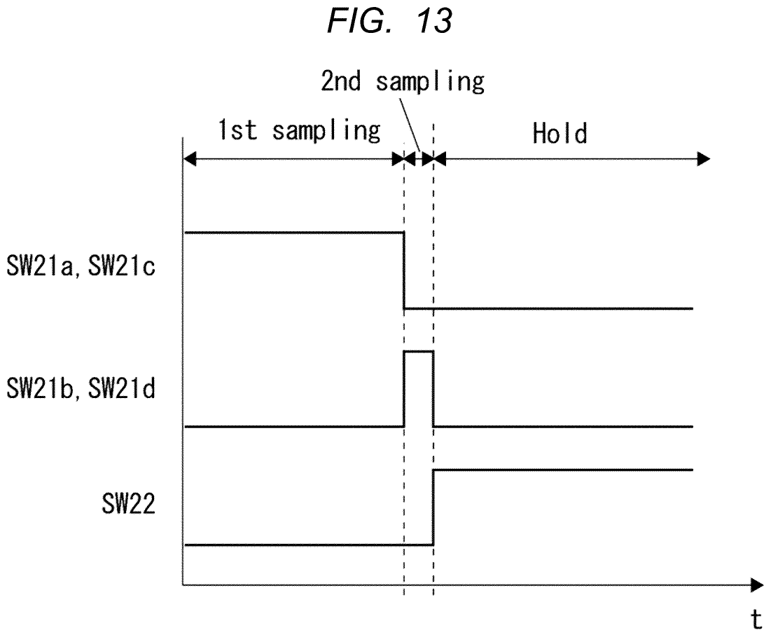

FIG. 13 is a timing chart showing the operation of the semiconductor device 2b. Each switch is assumed to turn off by a low-level control signal and turn on by a high-level control signal. The operation modes of the semiconductor device 2b include at least a sampling mode and a hold mode. The sampling mode is composed of a first sampling mode and a second sampling mode.

First, in the first sampling mode, the switches SW21a, SW21c indicate an on state, the switches SW21b, SW21d indicate an off state, and the switch SW22 indicates an off state. Accordingly, at the node Ns (the other end of the capacitor element Cs and the non-inverting input terminal of the comparator 221) and the node Ndac (one end of the capacitor element Cs), charges corresponding to the common voltage Vcm are accumulated respectively. As a result, the voltage Vs at the node Ns and the voltage Vdac at the node Ndac both indicate the common voltage Vcm.

Subsequently, in the second sampling mode, switches SW21a and SW21c switch from on to off, and switches SW21b and SW21d switch from off to on. As a result, the input voltage Vin is sampled. That is, at the node Ns (the other end of the capacitor element Cs), a charge corresponding to the input voltage Vin is accumulated. As a result, the voltage Vs at the node Ns ideally indicates the input voltage Vin.

Also, in the second sampling mode, the AD converter 212 converts the input voltage Vin, which was sampled and held in the first sampling mode, into a digital signal and outputs it. The DA converter 214 converts the output signal of the AD converter 212 into an analog voltage and outputs it to the node Ndac. As a result, the voltage Vdac at the node Ndac ideally indicates the input voltage Vin.

Subsequently, in the hold mode, switches SW21b and SW21d switch from on to off, and switch SW22 switches from off to on. As a result, the difference in potential between the sampled input voltage Vin and the output voltage of the signal cancellation circuit 21b is held in the capacitor element Cs. At this time, the negative feedback circuit 22a generates an analog voltage such that the voltage Vs at the non-inverting input terminal of the comparator 221 indicates the reference voltage Vss, that is, the voltage Vdac at the node Ndac indicates the reference voltage Vss, and outputs it to the node Ndac.

Here, in the semiconductor device 2b, the voltage Vs at the node Ns, which is one end of the capacitor element Cs, and the voltage Vdac at the node Ndac, which is the other end, behave so as to cancel each other's signal components. That is, the semiconductor device 2b does not cause errors due to dielectric relaxation phenomena by controlling the potential difference between the node Ns and the node Ndac to always be constant. However, the voltage Vm at the non-inverting input terminal of the comparator 221 also cancels the component of the input voltage Vin (input signal component).

Therefore, the semiconductor device 2b uses the adder circuit 23 to add the input signal component (the AD conversion result of the input voltage Vin) output from the AD converter 212 and the signal component that was not cancelled by the signal cancellation circuit 21b and output from the successive comparison register circuit 222, and outputs the sum as a digital output signal ADOUT. As a result, the semiconductor device 2b can output a high-precision digital output signal ADOUT with cancelled errors.

Thus, the semiconductor device 2b can achieve the same level of effect as the semiconductor device 2a by waiting in a state where the common voltage Vcm is applied to the capacitor element Cs when the input voltage Vin is not supplied in the first sampling mode. Also, the semiconductor device 2b can achieve the same level of effect as the semiconductor device 2a by applying the input voltage Vin to the node Ns and applying a voltage equivalent to the input voltage Vin obtained from the signal cancellation circuit output to the node Ndac in the second sampling mode. However, a greater effect can be expected when the input voltage Vin does not change significantly (i.e., when the input voltage Vin behaves like DC) in the second sampling mode.

### Third Embodiment

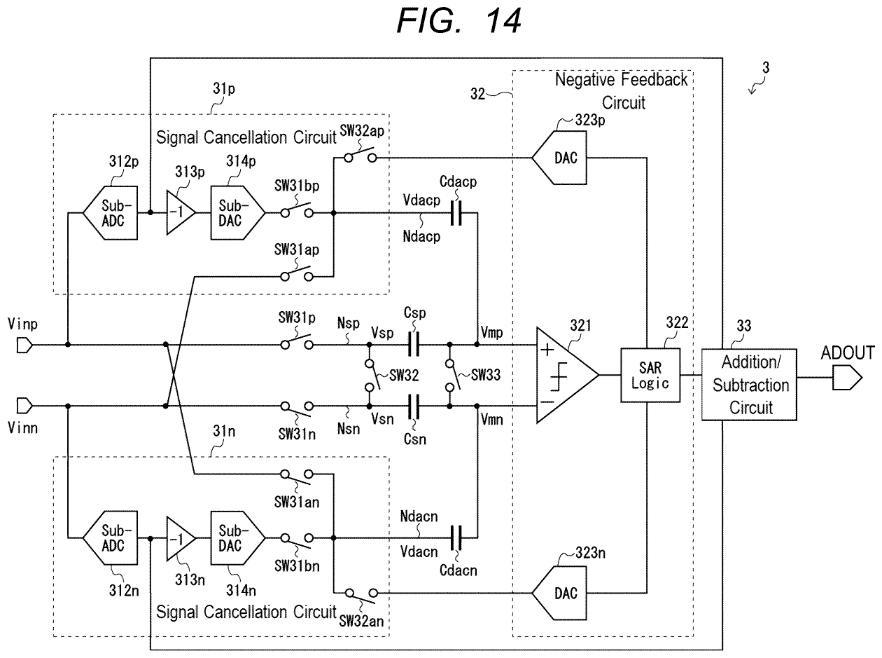

FIG. 14 is a circuit diagram showing a configuration example of a semiconductor device 3 according to the third embodiment. While the semiconductor device 1 is a single-ended AD converter, the semiconductor device 3 is an AD converter that performs AD conversion for differential input signals.

Specifically, the semiconductor device 3 includes signal cancellation circuits 31p, 31n, a negative feedback circuit 32, an addition/subtraction circuit 33, capacitor elements Csp, Csn, capacitor elements Cdacp, Cdacn, switches SW31p, SW31n, SW32, and SW33. The negative feedback circuit 32 includes a comparator 321, a sequential comparison register circuit 322, DA converters 323p and 323n.

First, in the semiconductor device 3, the signal cancellation circuit 31p, the comparator 321, the sequential comparison register circuit 322, the DA converter 323p, the capacitor elements Csp, Cdacp, and the switches SW31p, SW32, SW33 are mainly used as a circuit for processing one of a pair of differential input signals, the positive side input signal (input voltage) Vinp. The signal cancellation circuit 31p, the comparator 321, the sequential comparison register circuit 322, the DA converter 323p, the capacitor elements Csp, Cdacp, and the switches SW31p, SW32, SW33 correspond to the signal cancellation circuit 11, the comparator 121, the sequential comparison register circuit 122, the DA converter 123, the capacitor elements Cs, Cdac, and the switches SW11, SW12, SW13 in the semiconductor device 1 shown in FIG. 1, respectively.

Also, in the semiconductor device 3, the signal cancellation circuit 31n, the comparator 321, the sequential comparison register circuit 322, the DA converter 323n, the capacitor elements Csn, Cdacn, and the switches SW31n, SW32, SW33 are mainly used as a circuit for processing the other of a pair of differential input signals, the negative side input signal (input voltage) Vinn. The signal cancellation circuit 31n, the comparator 321, the sequential comparison register circuit 322, the DA converter 323n, the capacitor elements Csn, Cdacn, and the switches SW31n, SW32, SW33 correspond to the signal cancellation circuit 11, the comparator 121, the sequential comparison register circuit 122, the DA converter 123, the capacitor elements Cs, Cdac, and the switches SW11, SW12, SW13 in the semiconductor device 1 shown in FIG. 1, respectively.

The capacitor element Csp is provided between the non-inverting input terminal of the comparator 321 and the node Nsp. The switch SW31p is provided between the input terminal Vinp and the node Nsp (one end of the capacitor element Csp). The capacitor element Csn is provided between the inverting input terminal of the comparator 321 and the node Nsn. The switch SW31n is provided between the input terminal Vinn and the node Nsn (one end of the capacitor element Csn). The switch SW32 is provided between the node Nsp and the node Nsn. The switch SW33 is provided between the non-inverting and inverting input terminals of the comparator 321.

The capacitor element Cdacp is provided between the non-inverting input terminal of the comparator 321 and the node Ndacp. The signal cancellation circuit 31p is provided between the input terminal Vinp and the node Ndacp (one end of the capacitor element Cdacp).

The signal cancellation circuit 31p includes a sub AD converter 312p, an inversion circuit 313p, a sub DA converter 314p, switches SW31ap, SW31bp, and SW32ap. The AD converter 312p, inverting circuit 313p, DA converter 314p, switch SW31ap, switch SW31bp, and switch SW32ap each correspond to the AD converter 112, inverting circuit 113, DA converter 114, switch SW11a, switch SW11b, and switch SW12a provided in the signal canceling circuit 11 shown in FIG. 1. In the signal canceling circuit 31p, by using the negative side input voltage Vinn (i.e., the voltage obtained by inverting the input voltage Vinp), a circuit corresponding to the inverting circuit 111 is unnecessary. Specifically, the switch SW31ap is provided between the input terminal Vinn and the node Ndacp.

The capacitive element Cdacn is provided between the inverting input terminal of the comparator 321 and the node Ndacn. The signal canceling circuit 31n is provided between the input terminal Vinn and the node Ndacn (one end of the capacitive element Cdacn).

The signal canceling circuit 31n includes a sub AD converter 312n, an inverting circuit 313n, a sub DA converter 314n, a switch SW31an, a switch SW31bn, and a switch SW32an. The AD converter 312n, inverting circuit 313n, DA converter 314n, switch SW31an, switch SW31bn, and switch SW32an each correspond to the AD converter 112, inverting circuit 113, DA converter 114, switch SW11a, switch SW11b, and switch SW12a provided in the signal canceling circuit 11 shown in FIG. 1. In the signal canceling circuit 31n, by using the positive side input voltage Vinp (i.e., the voltage obtained by inverting the input voltage Vinn), a circuit corresponding to the inverting circuit 111 is unnecessary. Specifically, the switch SW31an is provided between the input terminal Vinp and the node Ndacn.

The successive comparison register circuit 322 outputs a digital signal (a control signal that controls each switch of the DA converters 123p and 123n) according to the comparison result of the comparator 321, and also outputs an output signal of a determined digital value. The DA converter 323p converts the digital signal output from the successive comparison register circuit 322 into an analog voltage and outputs it. The switch SW32ap is provided between the output of the DA converter 323p and the node Ndacp. The DA converter 323n converts the digital signal output from the successive comparison register circuit 322 into an analog voltage and outputs it. The switch SW32an is provided between the output of the DA converter 323n and the node Ndacn.

The adder-subtractor circuit 33 adds the difference between the output of the AD converter 312p and the output of the AD converter 312n and the output of the successive comparison register circuit 322, and outputs the result of the addition as a digital output signal ADOUT.

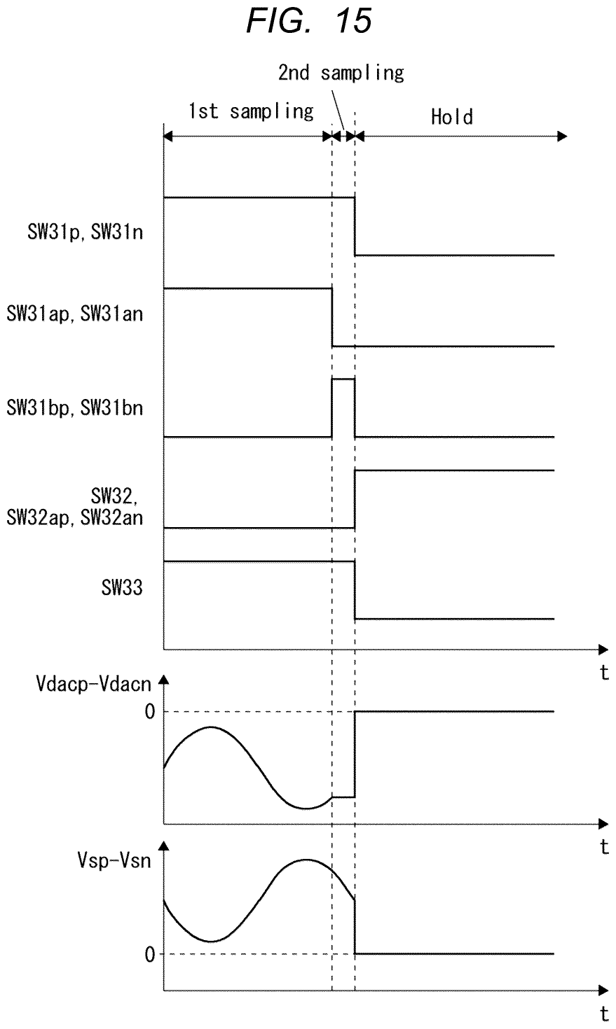

FIG. 15 is a timing chart showing the operation of the semiconductor device 3. Each switch is assumed to turn off by a low-level control signal and turn on by a high-level control signal. The operation modes of the semiconductor device 3 include at least a sampling mode and a hold mode. The sampling mode is composed of a first sampling mode and a second sampling mode.

First, in the first sampling mode, the switches SW31p, SW31n, SW31ap, SW31an are on, the switches SW31bp, SW31bn, SW32, SW32ap, SW32an are off, and the switch SW33 is on. As a result, the input voltages Vinp and Vinn are sampled. That is, a charge corresponding to the input voltage Vinp is accumulated at the node Nsp (one end of the capacitive element Csp), and a charge corresponding to the input voltage Vinn is accumulated at the node Nsn (one end of the capacitive element Csn). As a result, the voltage Vsp at the node Nsp ideally indicates the input voltage Vinp, and the voltage Vsn at the node Nsn ideally indicates the input voltage Vinn. Also, a charge corresponding to the voltage Vinn obtained by inverting the input voltage Vinp is accumulated at the node Ndacp (one end of the capacitive element Cdacp), and a charge corresponding to the voltage Vinp obtained by inverting the input voltage Vinn is accumulated at the node Ndacn (one end of the capacitive element Cdacn). As a result, the voltage Vdacp at node Ndacp ideally indicates the voltage Vinn, and the voltage Vdacn at node Ndacn ideally indicates the voltage Vinp.

Subsequently, in the second sampling mode, switches SW31ap, SW31an switch from on to off, and switches SW31bp, SW31bn switch from off to on. As a result, the AD converter 312p converts the input voltage Vinp, which was sampled and held in the first sampling mode, into a digital signal and outputs it. The inverting circuit 313p inverts the output signal of the AD converter 312p and outputs it. The DA converter 314p converts the output signal of the inverting circuit 313p into an analog voltage and outputs it to the node Ndacp. Also, the AD converter 312n converts the input voltage Vinn, which was sampled and held in the first sampling mode, into a digital signal and outputs it. The inverting circuit 313n inverts the output signal of the AD converter 312n and outputs it. The DA converter 314n converts the output signal of the inverting circuit 313n into an analog voltage and outputs it to the node Ndacn.

Afterwards, in the hold mode, switches SW31p, SW31n switch from on to off, switches SW31bp, SW31bn switch from on to off, switches SW32, SW32ap, SW32an switch from off to on, and switch SW33 switches from on to off. As a result, the sampled input voltages Vinp, Vinn are held in the capacitive elements Csp, Csn, respectively. Also, the sampled output voltages of DA converter 314p (equivalent to voltage Vinn) and DA converter 314n (equivalent to voltage Vinp) are held in the capacitive elements Cdacp, Cdacn, respectively.

Here, by turning on the switch SW32, nodes Nsp and Nsn are differentially shorted, and the negative feedback circuit 32 controls the voltages Vdacp and Vdacn at nodes Ndacp and Ndacn, respectively, so that the voltage Vmp at the non-inverting input terminal of comparator 321 and the voltage Vmn at the inverting input terminal of comparator 321 match.

Here, in the semiconductor device 3, errors occur in the capacitive elements Csp and Csn due to dielectric relaxation phenomena, and errors of opposite polarity occur in the capacitive elements Cdacp and Cdacn due to dielectric relaxation phenomena. Therefore, the difference voltage between the voltage Vmp at the non-inverting input terminal of comparator 321, to which the other ends of capacitive element Csp and capacitive element Cdacp are commonly connected, and the voltage Vmn at the inverting input terminal of comparator 321, to which the other ends of capacitive element Csn and capacitive element Cdacn are commonly connected, cancels out these error components. However, the components of the input voltage Vin (input signal components) are also cancelled at the voltages Vmp and Vmn at the non-inverting input terminal of comparator 321.

Therefore, the semiconductor device 3 uses the adder-subtractor 33 to add the input signal component (the AD conversion result of the input voltage Vinp) output from the AD converter 312p, the input signal component (the AD conversion result of the input voltage Vinn) output from the AD converter 312n, and the signal component that was not cancelled by the signal cancellation circuits 31p, 31n and output from the successive comparison register circuit 322, and outputs the sum as the digital output signal ADOUT. As a result, the semiconductor device 3 can output a high-accuracy digital output signal ADOUT, from which the setting error has been cancelled.

In this way, the semiconductor device 3 according to the present embodiment can achieve effects equivalent to those of the semiconductor device 1.

### First Modified Example of Semiconductor Device 3

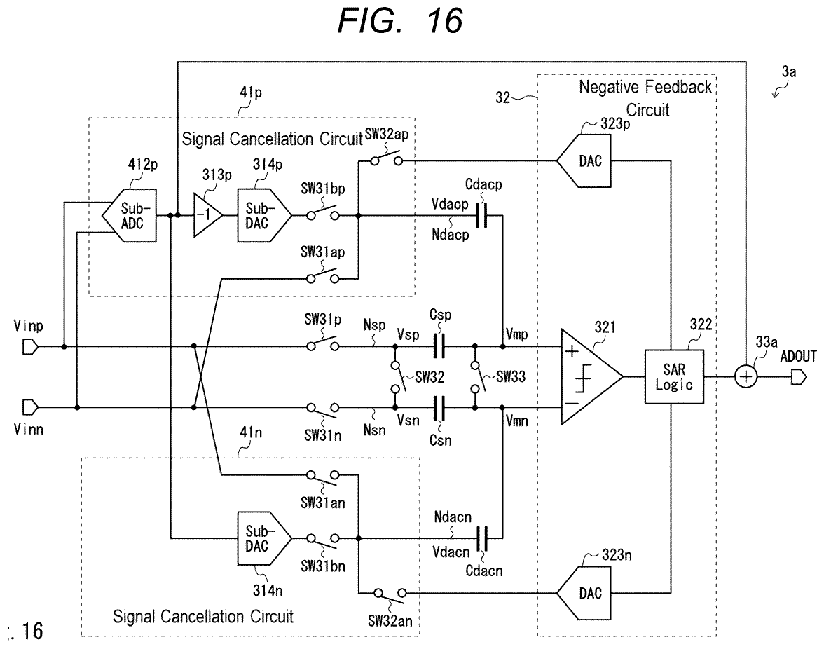

FIG. 16 is a circuit diagram showing a first modified example of the semiconductor device 3 as the semiconductor device 3a. Compared with the semiconductor device 3, the semiconductor device 3a includes signal cancellation circuits 41p, 42n instead of the signal cancellation circuits 31p, 31n, and an adder 33a instead of the adder-subtractor 33. The signal cancellation circuit 41p includes an AD converter 412p that performs AD conversion on a differential input signal, instead of the single-ended AD converter 312p, compared with the signal cancellation circuit 31p. The signal cancellation circuit 41n is equipped without the AD converter 312n and the inversion circuit 313n, compared to the signal cancellation circuit 41n. In the signal cancellation circuit 41n, the DA converter 314n is configured to convert the output signal of the AD converter 412p into an analog voltage. The other configurations of the semiconductor device 3a are the same as those of the semiconductor device 3, and therefore, the description thereof is omitted.

The semiconductor device 3a can achieve an effect equivalent to that of the semiconductor device 3. Furthermore, the semiconductor device 3a can reduce the number of AD converters, thereby reducing the circuit scale.

Although the invention made by the inventor has been specifically described based on the embodiment, the present invention is not limited to the embodiment already described, and it is needless to say that various modifications can be made without departing from the gist thereof.

Furthermore, this disclosure can be realized by executing a computer program on a CPU (Central Processing Unit) for some or all of the processing of the semiconductor devices 1 to 3.

The program described above includes a group of instructions (or software code) for causing a computer to perform one or more functions described in the embodiment when loaded into a computer. The program may be stored in a non-transitory computer-readable medium or a tangible storage medium. Not limited to, but as an example, the computer-readable medium or tangible storage medium includes RAM (Random-Access Memory), ROM (Read-Only Memory), flash memory, SSD (Solid-State Drive) or other memory technologies, CD-ROM, DVD (Digital Versatile Disc), Blu-ray (registered trademark) disc or other optical disc storage, magnetic cassette, magnetic tape, magnetic disk storage or other magnetic storage devices. The program may be transmitted on a temporary computer-readable medium or communication medium. Not limited to, but as an example, the temporary computer-readable medium or communication medium includes electrical, optical, acoustic, or other forms of propagation signals.

What is claimed is:

1. A semiconductor device comprising:
a first capacitive element;
a signal cancellation circuit that generates a first voltage corresponding to a first input voltage in a sampling mode, applies it to one end of the first capacitive element, and in a hold mode after the sampling mode, maintains the generated first voltage and applies it to one end of the first capacitive element;
a sampling circuit that samples the first input voltage in the sampling mode, and in the hold mode, maintains a second voltage corresponding to the sampled first input voltage and applies it to the other end of the first capacitive element;
a negative feedback circuit that generates an output signal corresponding to the voltage at the other end of the first capacitive element in the hold mode, and applies a feedback signal corresponding to the output signal to one end of the first capacitive element;
a first AD converter that performs AD conversion on the first input voltage; and
an addition-and-subtraction circuit that performs addition and subtraction of the output signal of the negative feedback circuit and the output signal of the first AD converter, and outputs the result.

2. The semiconductor device according to claim 1, wherein the sampling circuit comprises:
a second capacitive element connected at one end to the other end of the first capacitive element;
a first switch that applies the first input voltage to the other end of the second capacitive element in the sampling mode and holds the first input voltage in the second capacitive element in the hold mode; and
a second switch that transitions the voltage at the other end of the second capacitive element to a reference voltage in the hold mode, thereby transitioning the voltage at one end of the second capacitive element to the second voltage.

3. The semiconductor device according to claim 2, wherein the signal cancellation circuit comprises:
a first inversion circuit that generates a voltage that inverts the first input voltage;
a sub-AD converter that samples the first input voltage in the sampling mode and converts the sampled first input voltage into a digital signal while holding it in the hold mode;
a second inversion circuit that inverts and outputs the output signal of the sub-AD converter;
a sub-DA converter that converts the output signal of the second inversion circuit into an analog voltage; and
a selection circuit that selects and outputs the voltage generated by the first inversion circuit as the first voltage in the sampling mode, and selects and outputs the analog voltage output from the sub-AD converter as the first voltage in the hold mode.

4. The semiconductor device according to claim 3, wherein the first AD converter is constituted by the sub-AD converter.

5. The semiconductor device according to claim 3, wherein the sub-DA converter comprises:
a plurality of sub-capacitive elements and a plurality of sub-switches provided corresponding to each of the plurality of sub-capacitive elements; and
the plurality of sub-capacitive elements are also used as the first capacitive element.

6. The semiconductor device according to claim 2, wherein the signal cancellation circuit is configured to apply a common voltage or its inverted voltage to one end of the first capacitive element as the first voltage in a first sampling mode constituting the sampling mode, and to apply a voltage that inverts the first input voltage to one end of the first capacitive element as the first voltage in a second sampling mode, and
wherein the sampling circuit is configured to apply the common voltage to the other end of the second capacitive element in the first sampling mode, and to apply the first input voltage to the other end of the second capacitive element in the second sampling mode.

7. The semiconductor device according to claim 2, the signal cancellation circuit generates the first voltage of an amplitude corresponding to the capacitance values of the first and second capacitive elements, according to claim 2 of the semiconductor device.

8. The semiconductor device according to claim 2, wherein the negative feedback circuit comprises:
a comparator where the voltage at the other end of the first capacitive element is supplied to one input terminal and a reference voltage is supplied to the other input terminal;
a successive comparison register circuit that generates a digital output signal according to the comparison result of the comparator; and
a DA converter that converts the output signal generated by the successive comparison register circuit into an analog voltage and outputs it as the feedback signal;
wherein the addition-and-subtraction circuit performs addition and subtraction of the output signal generated by the successive comparison register circuit and the output signal of the first AD converter, and outputs the result.

9. The semiconductor device according to claim 3, wherein the negative feedback circuit comprises:
a comparator where the voltage at the other end of the first capacitive element is supplied to one input terminal and a reference voltage is supplied to the other input terminal; and
a successive comparison register circuit that generates a digital output signal according to the comparison result of the comparator,
wherein the negative feedback circuit uses the sub-DA converter to convert the output signal generated by the successive comparison register circuit into an analog voltage and outputs it as the feedback signal,
wherein the addition-and-subtraction circuit performs addition and subtraction of the output signal generated by the successive comparison register circuit and the output signal of the first AD converter, and outputs the result.

10. The semiconductor device according to claim 2, further comprises a second AD converter that performs AD conversion on the output signal of the negative feedback circuit,
wherein the negative feedback circuit comprises an operational amplifier that generates an output signal corresponding to the potential difference between the voltage at the other end of the first capacitive element and the reference voltage, and a feedback signal corresponding thereto,
wherein the addition-and-subtraction circuit performs addition and subtraction of the output signal of the second AD converter and the output signal of the first AD converter, and outputs the result.

11. The semiconductor device according to claim 1, wherein the sampling circuit comprises a first switch that samples the first input voltage in the sampling mode, and applies it to the other end of the first capacitive element as the second voltage while holding the sampled first input voltage in the hold mode.

12. The semiconductor device according to claim 11, wherein the signal cancellation circuit comprises:
a sub-AD converter that samples the first input voltage in the sampling mode and converts it into a digital signal while holding the sampled first input voltage in the hold mode;
a sub-DA converter that converts the output signal of the sub-AD converter into an analog voltage; and
a selection circuit that outputs the first input voltage as the first voltage in the sampling mode and selects and outputs the analog voltage output from the sub-AD converter as the first voltage in the hold mode.

13. The semiconductor device according to claim 12, wherein the first AD converter is constituted by the sub-AD converter.

14. The semiconductor device according to claim 12,
wherein the sub-DA converter comprises multiple sub-capacitive elements and multiple sub-switches provided corresponding to each of the multiple sub-capacitive elements, and
wherein the multiple sub-capacitive elements are also used as the first capacitive element.

15. The semiconductor device according to claim 11,
wherein the signal cancellation circuit is configured such that in the first sampling mode, which constitutes the sampling mode, an intermediate voltage between the first input voltage and the voltage inverted from the first input voltage is applied to one end of the first capacitive element as the first voltage, and in the second sampling mode, the first input voltage is applied to one end of the first capacitive element as the first voltage, and
wherein the sampling circuit is configured to apply the intermediate voltage to the other end of the first capacitive element in the first sampling mode, and to apply the first input voltage to the other end of the first capacitive element in the second sampling mode.

16. The semiconductor device according to claim 11, wherein the negative feedback circuit comprises:
a comparator supplied with the voltage at the other end of the first capacitive element at one input terminal and a reference voltage at the other input terminal;
a successive comparison register circuit that generates a digital output signal according to the comparison result of the comparator; and
a DA converter that converts the output signal generated by the successive comparison register circuit into an analog voltage and outputs it as the feedback signal,
wherein the addition-and-subtraction circuit performs addition and subtraction of the output signal generated by the successive comparison register circuit and the output signal of the first AD converter, and outputs the result.

17. The semiconductor device according to claim 12, wherein the negative feedback circuit comprises:
a comparator supplied with the voltage at the other end of the first capacitive element at the non-inverting input terminal and a reference voltage at the inverting input terminal; and
a successive comparison register circuit that generates a digital output signal according to the comparison result of the comparator,
wherein the negative feedback circuit uses the sub-DA converter to convert the output signal generated by the successive comparison register circuit into an analog voltage and outputs it as the feedback signal,
wherein the addition-and-subtraction circuit performs addition and subtraction of the output signal generated by the successive comparison register circuit and the output signal of the first AD converter, and outputs the result.

18. The semiconductor device according to claim 11, wherein the negative feedback circuit further comprises:
a second AD converter that performs AD conversion on the output signal of the negative feedback circuit; and
an operational amplifier circuit that generates an output signal and a corresponding feedback signal according to the potential difference between the voltage at the other end of the first capacitive element and the reference voltage,
wherein the addition-and-subtraction circuit performs addition and subtraction of the output signal of the second AD converter and the output signal of the first AD converter, and outputs the result.

19. The semiconductor device according to claim 1, further comprises:
a third capacitive element;
a second signal cancellation circuit that, in the sampling mode, generates a third voltage corresponding to the second input voltage that forms a differential input signal with the first input voltage, applies it to one end of the third capacitive element, and in the hold mode, holds the generated third voltage and applies it to one end of the third capacitive element; and
a second sampling circuit that, in the sampling mode, samples the second input voltage, and in the hold mode, holds a fourth voltage corresponding to the sampled second input voltage and applies it to the other end of the third capacitive element,
wherein the negative feedback circuit is configured to, in the hold mode, generate an output signal corresponding to the potential difference between the voltage at the other end of the first capacitive element and the voltage at the other end of the third capacitive element, apply a feedback signal corresponding to the output signal to one end of the first capacitive element, and apply a second feedback signal corresponding to the output signal to one end of the third capacitive element.

20. The semiconductor device according to claim 10, wherein the sampling circuit comprises:
a second capacitive element connected at one end to the other end of the first capacitive element;
a first switch that, in the sampling mode, applies the first input voltage to the other end of the second capacitive element, and in the hold mode, holds the first input voltage in the second capacitive element; and
a second switch that, in the hold mode, transitions the voltage at the other end of the second capacitive element to a reference voltage, thereby transitioning the voltage at one end of the second capacitive element to the second voltage,
wherein the second sampling circuit comprises:
a fourth capacitive element connected at one end to the other end of the third capacitive element;
a third switch that, in the sampling mode, applies the second input voltage to the other end of the fourth capacitive element, and in the hold mode, holds the second input voltage in the fourth capacitive element; and
a fourth switch that, in the hold mode, transitions the voltage at the other end of the fourth capacitive element to a reference voltage, thereby transitioning the voltage at one end of the fourth capacitive element to the fourth voltage;
wherein the signal cancellation circuit comprises:
a sub-AD converter that, in the sampling mode, samples the first input voltage, and in the hold mode, holds the sampled first input voltage while converting it to a digital signal;
a first inversion circuit that inverts and outputs the output signal of the sub-AD converter;
a sub-DA converter that converts the output signal of the first inversion circuit to an analog voltage; and
a selection circuit that, in the sampling mode, selects the second input voltage and outputs it as the first voltage, and in the hold mode, selects the analog voltage output from the sub-AD converter and outputs it as the first voltage,
wherein the second signal cancellation circuit comprises:
a second sub-AD converter that, in the sampling mode, samples the second input voltage, and in the hold mode, holds the sampled second input voltage while converting it to a digital signal;
a second inversion circuit that inverts and outputs the output signal of the second sub-AD converter;
a second sub-DA converter that converts the output signal of the second inversion circuit to an analog voltage; and
a second selection circuit that, in the sampling mode, selects the first input voltage and outputs it as the third voltage, and in the hold mode, selects the analog voltage output from the second sub-AD converter and outputs it as the third voltage.
